(19) United States
(12) Patent Application Publication
(10) Pub. No.: US 2024/0324352 A1
(43) Pub. Date: Sep. 26, 2024

(54) DISPLAY PANEL AND DISPLAY APPARATUS

(71) Applicants: Chengdu BOE Optoelectronics Technology Co., Ltd., Sichuan (CN); BOE Technology Group Co., Ltd., Beijing (CN)

(72) Inventors: Meng LI, Beijing (CN); Yao HUANG, Beijing (CN); Tianyi CHENG, Beijing (CN); Lili DU, Beijing (CN); Hongjun ZHOU, Beijing (CN); Zhenhua ZHANG, Beijing (CN)

(73) Assignees: Chengdu BOE Optoelectronics Technology Co., Ltd., Sichuan (CN); BOE Technology Group Co., Ltd., Beijing (CN)

(21) Appl. No.: 18/575,185

(22) PCT Filed: Sep. 21, 2022
(86) PCT No.: PCT/CN2022/120054

§ 371 Date: Dec. 28, 2023

(30) Foreign Application Priority Data
Dec. 16, 2021 (CN) 202111545333.9

(51) Int. Cl. H10K 59/131; H10K 59/122; H10K 59/35

(52) U.S. Cl. CPC H10K 59/131; H10K 59/122; H10K 59/353

(57) ABSTRACT

Provided are a display panel and a display apparatus. The display panel includes a base substrate, a fifth conductive layer, an electrode layer and a pixel defining layer. The electrode layer includes a plurality of electrode portions, at least one of the electrode portions comprises a body portion and a supplemental portion which are connected with each other, and an orthographic projection of the supplemental portion on the base substrate at least partially overlaps with an orthographic projection of a corresponding power line on the base substrate.

### CROSS-REFERENCES TO RELATED APPLICATIONS

This application claims priority to Chinese Patent Application No. 202111545333.9, titled “Display Panel and Display Apparatus” and submitted on Dec. 16, 2021, the content of which is hereby incorporated in its entirety as a part of this application.

### TECHNICAL FIELD

The present disclosure relates to the field of display technology, and in particular, to a display panel and a display apparatus.

### BACKGROUND

In the related art, a driving transistor in a pixel driving circuit has a hysteresis phenomenon, and the hysteresis phenomenon of the driving transistor causes a flicker problem of the display panel.

It should be noted that the information disclosed in the background section is only for enhancing the understanding of the background of the present disclosure, and therefore may include information that does not constitute prior art known to those of ordinary skill in the art.

### SUMMARY

According to an aspect of the present disclosure, there is provided a display panel, including: a base substrate, a fifth conductive layer, an electrode layer, and a pixel defining layer. The fifth conductive layer is located on a side of the base substrate, and the fifth conductive layer includes a power line; the electrode layer is located on a side of the fifth conductive layer away from the base substrate, the electrode layer includes a plurality of electrode portions, the electrode portion includes a body portion and a supplemental portion which are connected with each other, and an orthographic projection of the supplemental portion on the base substrate at least partially overlaps with an orthographic projection of the power line on the base substrate; the pixel defining layer is located on a side of the electrode layer away from the base substrate and including a plurality of pixel openings, the plurality of pixel openings are arranged in one-to-one correspondence with the plurality of electrode portions, and orthographic projections of the pixel openings on the base substrate overlap with orthographic projections of body portions of corresponding electrode portions on the base substrate.

In an example embodiment of the present disclosure, the plurality of electrode portions include a first electrode portion, a second electrode portion and a third electrode portion of three different colors;
an overlapping area between an orthographic projection of the first electrode portion on the base substrate and the orthographic projection of the power line on the base substrate is larger than an overlapping area between an orthographic projection of the second electrode portion on the base substrate and the orthographic projection of the power line on the base substrate; and
the overlapping area between the orthographic projection of the first electrode portion on the base substrate and the orthographic projection of the power line on the base substrate is larger than an overlapping area between an orthographic projection of the third electrode portion on the base substrate and the orthographic projection of the power line on the base substrate.

In an example embodiment of the present disclosure, the first electrode portion is a B electrode portion corresponding to a blue sub-pixel unit, the second electrode portion is an R electrode portion corresponding to a red sub-pixel unit, and the third electrode portion is a G electrode portion corresponding to a green sub-pixel unit;
the overlapping area between the orthographic projection of the first electrode portion on the base substrate and the orthographic projection of the power line on the base substrate is larger than the overlapping area between the orthographic projection of the second electrode portion on the base substrate and the orthographic projection of the power line on the base substrate; and
the overlapping area between the orthographic projection of the second electrode portion on the base substrate and the orthographic projection of the power line on the base substrate is larger than the overlapping area between the orthographic projection of the third electrode portion on the base substrate and the orthographic projection of the power line on the base substrate.

In an example embodiment of the present disclosure, the display panel further includes a plurality of pixel driving circuits distributed in rows and columns, the pixel driving circuit includes a driving transistor and a fourth transistor, and a first electrode of the fourth transistor is connected to a data line, and a second electrode of the fourth transistor is connected to a first electrode of the driving transistor; and
an overlapping area between the orthographic projection of the second electrode portion on the base substrate and an orthographic projection of the data line on the base substrate is larger than an overlapping area between the orthographic projection of the third electrode portion on the base substrate and the orthographic projection of the data line on the base substrate, and the overlapping area between the orthographic projection of the third electrode portion on the base substrate and the orthographic projection of the data line on the base substrate is larger than an overlapping area between the orthographic projection of the first electrode portion on the base substrate and the orthographic projection of the data line on the base substrate.

In an example embodiment of the present disclosure, the plurality of electrode portions include: a plurality of R electrode portions, a plurality of G electrode portions and a plurality of B electrode portions, and two G electrode portions distributed along a column direction are provided between an R electrode portion and a B electrode portion which are adjacent in a row direction.

In an example embodiment of the present disclosure, an overlapping area between an orthographic projection of the R electrode portion on the base substrate and the orthographic projection of the power line on the base substrate is S1, an area of an orthographic projection of a body portion of the R electrode portion on the base substrate is S2, and S1/S2 is larger than or equal to 0.8 and less than or equal to 1.9.

In an example embodiment of the present disclosure, an overlapping area between an orthographic projection of the G electrode portion on the base substrate and the orthographic projection of the power line on the base substrate is S3, an area of an orthographic projection of a body portion of the G electrode portion on the base substrate is S4, and S3/S4 is larger than or equal to 1 and less than or equal to 1.7.

In an example embodiment of the present disclosure, an overlapping area between an orthographic projection of the B electrode portion on the base substrate and the orthographic projection of the power line on the base substrate is S5, an area of an orthographic projection of a body portion of the B electrode portion on the base substrate is S6, and S5/S6 is larger than or equal to 1.6 and less than or equal to 2.

In an example embodiment of the present disclosure, an area of an orthographic projection of a body portion of the R electrode portion on the base substrate is S2, an overlapping area between an orthographic projection of a supplemental portion of the R electrode portion on the base substrate and the orthographic projection of the power line on the base substrate is S7, and S7/S2 is larger than or equal to 0.04 and less than or equal to 1.14.

In an example embodiment of the present disclosure, a supplemental portion of a G electrode portion includes a first supplemental portion and a second supplemental portion;
in an R electrode portion and the G electrode portion located in a same row and adjacent columns:
an orthographic projection of the first supplemental portion of the G electrode portion on the base substrate is located on a side of an orthographic projection of a body portion of the G electrode portion on the base substrate facing an orthographic projection of the R electrode portion on the base substrate;
an orthographic projection of the second supplemental portion of the G electrode portion on the base substrate is located on a side of the orthographic projection of the body portion of the G electrode portion on the base substrate facing an orthographic projection of another G electrode portion on the base substrate; and
an area of the orthographic projection of the body portion of the G electrode portion on the base substrate is S4, an overlapping area between an orthographic projection of the supplemental portion of the G electrode portion on the base substrate and the orthographic projection of the power line on the base substrate is S8, and S8/S4 is larger than or equal to 0.1 and less than or equal to 0.8.

In an example embodiment of the present disclosure, a supplemental portion of the B electrode portion includes a third supplemental portion and a fourth supplemental portion;
in the B electrode portion and a G electrode portion located in a same row and adjacent columns:
an orthographic projection of the third supplemental portion of the B electrode portion on the base substrate is located on a side of an orthographic projection of a body portion of the B electrode portion on the base substrate facing an orthographic projection of the G electrode portion on the base substrate; and
an orthographic projection of the fourth supplemental portion of the B electrode portion on the base substrate is located on a side the orthographic projection of the body portion of the B electrode portion on the base substrate away from the orthographic projection of the third supplemental portion of the B electrode portion on the base substrate;
an area of the orthographic projection of the body portion of the B electrode portion on the base substrate is S6, an overlapping area between an orthographic projection of the supplemental portion of the B electrode portion on the base substrate and the orthographic projection of the power line on the base substrate is S9, and S9/S6 is larger than or equal to 0.1 and less than or equal to 0.5.

In an example embodiment of the present disclosure, the fifth conductive layer further includes a plurality of seventh bridge portions, and the plurality of seventh bridge portions are arranged in one-to-one correspondence with the plurality of electrode portions, and electrode portions are connected to corresponding seventh bridge portions through via holes;
an R electrode portion is connected to a seventh bridge portion through a first via hole, the R electrode portion includes a first side and a second side arranged oppositely, and orthographic projections of the first side and the second side of the R electrode portion on the base substrate extend along the column direction,
in the R electrode portion and a G electrode portion located in a same row and adjacent columns:
the orthographic projection of the first side of the R electrode portion on the base substrate is located between the orthographic projection of the second side of the R electrode portion on the base substrate and an orthographic projection of the G electrode portion on the base substrate; and
an extension line of the orthographic projection of the first side on the base substrate passes through an orthographic projection of the first via hole on the base substrate;
a B electrode portion is connected to a seventh bridge portion through a second via hole, the B electrode portion includes a third side and a fourth side arranged oppositely, orthographic projections of the third side and the fourth side of the B electrode portion on the base substrate extend along the column direction, and extension lines of the orthographic projections of the third side and the fourth side of the B electrode portion on the base substrate are located on both sides of an orthographic projection of the second via hole on the base substrate.

In an example embodiment of the present disclosure, the display panel further includes a pixel driving circuit, and the pixel driving circuit includes a driving transistor, a first transistor, a second transistor, a sixth transistor and a seventh transistor;
a first electrode of the first transistor is connected to a gate of the driving transistor, and a second electrode of the first transistor is connected to a first initialization signal line;
a first electrode of the second transistor is connected to the gate of the driving transistor, and a second electrode of the second transistor is connected to a second electrode of the driving transistor;
a first electrode of the sixth transistor is connected to the second electrode of the driving transistor;
a first electrode of the seventh transistor is connected to a second electrode of the sixth transistor, and a second electrode of the seventh transistor are connected to a second initialization signal line;
the display panel further includes a first active layer, a second active layer, and a fourth conductive layer;
the first active layer is located between the base substrate and the fifth conductive layer, and the first active layer includes a third active portion, a sixth active portion, a seventh active portion, a tenth active portion and an eleventh active portion;
the third active portion is used to form a channel region of the driving transistor;
the sixth active portion is used to form a channel region of the sixth transistor;
the seventh active portion is used to form a channel region of the seventh transistor;
the tenth active portion is connected between the seventh active portion and the sixth active portion; and
the eleventh active portion is connected between the sixth active portion and the third active portion;
the second active layer is located between the first active layer and the fifth conductive layer, and the second active layer includes a first active portion and a second active portion and a twelfth active portion;
the first active portion is used to form a channel region of the first transistor;
the second active portion is connected to the first active portion and is used to form a channel region of the second transistor, and
the twelfth active portion is connected to an end of the second active portion away from the first active portion; and
the fourth conductive layer is located between the second active layer and the fifth conductive layer, and the fourth conductive layer includes a second bridge portion and a third bridge portion, the second bridge portion is connected to the tenth active portion through a via hole, and the third bridge portion is connected to the eleventh active portion and the twelfth active portion through via holes, respectively; and
the second bridge portion and the third bridge portion are arranged oppositely in a column direction.

In an example embodiment of the present disclosure, the display panel includes a plurality of repetition units distributed along a row direction and a column direction, each of the repetition units includes two pixel driving circuits, the two pixel driving circuits includes a first pixel driving circuit and a second pixel driving circuit distributed along the row direction, and the first pixel driving circuit and the second pixel driving circuit are arranged in mirror symmetry;
the pixel driving circuit includes a driving transistor, a sixth transistor and a seventh transistor, a first electrode of the sixth transistor is connected to a second electrode of the driving transistor, a first electrode of the seventh transistor is connected to a second electrode of the sixth transistor, and a second electrode of the seventh transistor is connected to a second initialization signal line;
the display panel further includes a first active layer, and a fourth conductive layer;
the first active layer is located between the base substrate and the fifth conductive layer, and the first active layer includes a third active portion, a sixth active portion, a seventh active portion and a tenth active portion;
the third active portion is used to form a channel region of the driving transistor;
the sixth active portion is used to form a channel region of the sixth transistor;
the seventh active portion is used to form a channel region of the seventh transistor; and
the tenth active portion is connected between the seventh active portion and the sixth active portion; and
the fourth conductive layer is located between the first active layer and the fifth conductive layer, and the fourth conductive layer includes a first bridge portion and a second bridge portion, the second bridge portion is connected to the tenth active portion through a via hole, the first bridge portion and the repetition units are arranged in one-to-one correspondence, and the first bridge portion is connected to the power line through a via hole;
a distance between orthographic projections of second bridge portions adjacent in the row direction on the base substrate is equal to L5, a distance between orthographic projections of a second bridge portion and a first bridge portion adjacent in the row direction on the base substrate is equal to L6, and L5/L6 is larger than or equal to 0.8 and less than or equal to 1.2.

In an example embodiment of the present disclosure, the display panel includes a plurality of repetition units distributed along a row direction and a column direction, each of the repetition units includes two pixel driving circuits, the two pixel driving circuits include a first pixel driving circuit and a second pixel driving circuit distributed along the row direction, and the first pixel driving circuit and the second pixel driving circuit are arranged in mirror symmetry;
the pixel driving circuit includes a driving transistor, a fourth transistor and a fifth transistor, a first electrode of the fourth transistor is connected to a data line, a second electrode of the fourth transistor is connected to a first electrode of the driving transistor, a first electrode of the fifth transistor is connected to the power line, and a second electrode of the fifth transistor is connected to the first electrode of the driving transistor;
the display panel further includes a first active layer, and a fourth conductive layer:
the first active layer is located between the base substrate and the fifth conductive layer, and the first active layer further includes a third active portion, a fifth active portion, an eighth active portion and a ninth active portion:
the third active portion is used to form a channel region of the driving transistor;
the fifth active portion is used to form a channel region of the fifth transistor;
the eighth active portion is connected to a side of the fifth active portion away from the third active portion; and
the ninth active portion is connected between two eighth active portions in a same repetition unit; and
the fourth conductive layer is located between the first active layer and the fifth conductive layer, the fourth conductive layer includes a plurality of first bridge portions, the plurality of first bridge portions and the plurality of repetition units are arranged in one-to-one correspondence, the first bridge portion is connected to the ninth active portion through a via hole, and the first bridge portion is connected to the power line through a via hole;
the first bridge portion includes a first via hole connection portion used for connecting to the ninth active portion and two second via hole connection portions used for connecting to the power line, the two second via hole connections are connected at both sides of the first via hole connection portion, and the first bridge portion is provided with a notch between the first via hole connection portion and the second via hole connection portions;
the orthographic projection of the power line on the base substrate and an orthographic projection of the data line on the base substrate both extend along the column direction, and pixel driving circuits of each column are provided with one corresponding power line and one corresponding data line;
the data line includes a straight line extension portion, and an orthographic projection of the straight line extension portion on the base substrate extends in a straight line along the column direction;
in a same repetition unit:
orthographic projections of two data lines on the base substrate are located between orthographic projections of two power lines on the base substrate, a minimum distance in the row direction between an orthographic projection of the straight line extension portion of a data line on the base substrate and an orthographic projection of a power line adjacent to the data line on the base station is L1, a size of an orthographic projection of the notch on the base substrate in the row direction is L4, and L1/L4 is larger than or equal to 0.9 and less than or equal to 1.1.

In an example embodiment of the present disclosure, the display panel includes a plurality of repetition units distributed along a row direction and a column direction, each of the repetition units includes two pixel driving circuits, the two pixel driving circuits includes a first pixel driving circuit and a second pixel driving circuit distributed along the row direction, and the first pixel driving circuit and the second pixel driving circuit are arranged in mirror symmetry;
the pixel driving circuit includes a driving transistor, a fourth transistor and a fifth transistor, a first electrode of the fourth transistor is connected to a data line, a second electrode of the fourth transistor is connected to a first electrode of the driving transistor, a first electrode of the fifth transistor is connected to the power line, and a second electrode of the fifth transistor is connected to the first electrode of the driving transistor;
the orthographic projection of the power line on the base substrate and an orthographic projection of the data line on the base substrate both extend along the column direction, and pixel driving circuits of each column are provided with one corresponding power line and one corresponding data line;
the data line includes a straight line extension portion, and an orthographic projection of the straight line extension portion on the base substrate extends in a straight line along the column direction;
in a same repetition unit:
orthographic projections of two data lines on the base substrate are located between orthographic projections of two power lines on the base substrate, a minimum distance in the row direction between an orthographic projection of the straight line extension portion on the base substrate and an orthographic projection of a power line adjacent to the data line on the base substrate is L1, and a minimum distance in the row direction between orthographic projections of straight line extension portions of two data lines on the base substrate is L2, and L1/L2 is larger than or equal to 1.4.

In an example embodiment of the present disclosure, the display panel includes a pixel driving circuit, and the pixel driving circuit includes a driving transistor, a fourth transistor and a fifth transistor;
a first electrode of the fourth transistor is connected to a data line, and a second electrode of the fourth transistor is connected to a first electrode of the driving transistor;
a first electrode of the fifth transistor is connected to the power line, and a second electrode of the fifth transistor is connected to the first electrode of the driving transistor;
the orthographic projection of the power line on the base substrate and an orthographic projection of the data line on the base substrate both extend along a column direction, and pixel driving circuits of each column are provided with one corresponding power line and one corresponding data line;
the data line includes a straight line extension portion, and an orthographic projection of the straight line extension portion on the base substrate extends in a straight line along the column direction;
a minimum distance in a row direction between an orthographic projection of the straight line extension portion of the data line on the base substrate and the orthographic projection of the power line on the base substrate is L1, and a size of orthographic projection of the straight line extension portion of the data line on the base substrate in the row direction is L3, and L1/L3 is larger than or equal to 1.4 and less than or equal to 3.

In an example embodiment of the present disclosure, the display panel includes a pixel driving circuit, and the pixel driving circuit includes a driving transistor, a first transistor and a second transistor;
a first electrode of the first transistor is connected to a gate of the driving transistor, and a second electrode of the first transistor is connected to a first initialization signal line;
a first electrode of the second transistor is connected to the gate of the driving transistor, and a second electrode of the second transistor is connected to a second electrode of the driving transistor;
the display panel further includes a first active layer and a second active layer;
the first active layer is located between the base substrate and the fifth conductive layer, and the first active layer includes a third active portion used to form a channel region of the driving transistor; and
the second active layer is located between the first active layer and the fifth conductive layer, and the second active layer includes a first active portion and a second active portion, the first active layer is used to form a channel region of the first transistor, and the second active portion is connected to the first active portion and is used to form a channel region of the second transistor;
the power line includes: a first extension portion, a second extension portion and a third extension portion, and the second extension portion is connected between the first extension portion and the third extension portion;
a size of an orthographic projection of the second extension portion on the base substrate in the row direction is larger than a size of an orthographic projection of the first extension portion on the base substrate in the row direction, and the size of the orthographic projection of the second extension portion on the base substrate in the row direction is larger than a size of an orthographic projection of the third extension portion on the base substrate in the row direction; and
the orthographic projection of the second extension portion on the base substrate covers an orthographic projection of the first active portion on the base substrate and an orthographic projection of the second active portion on the base substrate.

In an example embodiment of the present disclosure, the display panel includes a plurality of repetition units distributed along a row direction and a column direction, each of the repetition units includes two pixel driving circuits, the two pixel driving circuits include a first pixel driving circuit and a second pixel driving circuit distributed along the row direction, and the first pixel driving circuit and the second pixel driving circuit are arranged in mirror symmetry;
pixel driving circuits of each column are provided with one corresponding power line, and in repetition units adjacent in the row direction, second extension portions of adjacent power lines are connected;
the pixel driving circuit includes a driving transistor and a capacitor, a first electrode of the capacitor is connected to a gate of the driving transistor, and a second electrode of the capacitor is connected to the power line;
the display panel further includes a first active layer and a second conductive layer;
the first active layer is located between the base substrate and the fifth conductive layer, and the first active layer includes a third active portion which is used to form a channel region of the driving transistor; and
the second conductive layer is located between the first active layer and the fifth conductive layer, and the second conductive layer includes a first conductive portion which is used to form the second electrode of the capacitor;
adjacent first conductive portions in a same repetition unit are connected.

In an example embodiment of the present disclosure, in the same repetition unit, adjacent first conductive portions are connected through a first connection portion;
the pixel driving circuit includes a driving transistor and a fifth transistor, a first electrode of the fifth transistor is connected to the power line, and a second electrode of the fifth transistor is connected to a first electrode of the driving transistor;
the first active layer further includes a fifth active portion, an eighth active portion and a ninth active portion:
the fifth active portion is used to form a channel region of the fifth transistor;
the eighth active portion is connected to a side of the fifth active portion away from the third active portion; and
the ninth active portion is connected between two eighth active portions in the same repetition unit;
the display panel further includes a first conductive layer and a fourth conductive layer;
the first conductive layer is located between the first active layer and the fifth conductive layer, and the first conductive layer includes an enable signal line, an orthographic projection of the enable signal line on the base substrate extends along the row direction and covers an orthographic projection of the fifth active portion on the base substrate, and a partial structure of the enable signal line is used to form a gate of the fifth transistor; and
the fourth conductive layer is located between the first conductive layer and the fifth conductive layer, and the fourth conductive layer includes a plurality of first bridge portions, the plurality of first bridge portions the plurality of repetition units are arranged in one-to-one correspondence, the first bridge portions is connected to the ninth active portion and the first connection portion through via holes, and the first bridge portion is connected to the power line through a via hole.

In an example embodiment of the present disclosure, the display panel includes a pixel driving circuit, and the pixel driving circuit includes a driving transistor, a fourth transistor, a sixth transistor, a seventh transistor and a capacitor;
a first electrode of the fourth transistor is connected to a data line, and a second electrode of the fourth transistor is connected to a first electrode of the driving transistor;
a first electrode of the sixth transistor is connected to a second electrode of the driving transistor;
a first electrode of the seventh transistor is connected to a second electrode of the driving transistor, and a second electrode of the seventh transistor is connected to a second initialization signal line;
a first electrode of the capacitor is connected to a gate of the driving transistor, and a second electrode of the capacitor is connected to the power line;
the display panel further includes a first active layer and a first conductive layer;
the first active layer is located between the base substrate and the fifth conductive layer, and the first active layer includes: a third active portion, a fourth active portion, a sixth active portion and a seventh active portion;
the third active portion is used to form a channel region of the driving transistor;
the fourth active portion is connected to a side of the third active portion and is used to form a channel region of the fourth transistor;
the sixth active portion is connected to a side of the third active portion away from the fourth active portion and is used to form a channel region of the sixth transistor; and
the seventh active portion is connected to a side of the sixth active portion away from the third active portion and is used to form a channel region of the seventh transistor;
the first conductive layer is located between the first active layer and the fifth conductive layer, and the first conductive layer includes a second gate line, an enable signal line, a second reset signal line and a second conductive portion;
an orthographic projection of the second gate line on the base substrate extends along the row direction and covers an orthographic projection of the fourth active portion on the base substrate, and a partial structure of the second gate line is used to form a gate of the fourth transistor;
an orthographic projection of the enable signal line on the base substrate extends along the row direction and covers an orthographic projection of the sixth active portion on the base substrate, and a partial structure of the enable signal line is used to form a gate of the sixth transistor;
an orthographic projection of the second reset signal line on the base substrate extends along the row direction and covers an orthographic projection of the seventh active portion on the base substrate, and a partial structure of the second reset signal line is used to form a gate of the seventh transistor; and
an orthographic projection of the second conductive portion on the base substrate covers an orthographic projection of the third active portion on the base substrate, and the second conductive portion is used to form a gate of the driving transistor and a first electrode of the capacitor;
in a same pixel driving circuit, the orthographic projection of the second conductive portion on the base substrate is located between the orthographic projection of the second gate line on the base substrate and the orthographic projection of the enable signal line on base substrate;
the orthographic projection of the second reset signal line on the base substrate is located at a side of the orthographic projection of the enable signal line on the base substrate away from the orthographic projection of the second conductive portion on the base substrate.

In an example embodiment of the present disclosure, a second gate line in pixel driving circuits of a current row is reused as a second reset signal line in pixel driving circuits of a preceding row.

In an example embodiment of the present disclosure, the pixel driving circuit further includes a first transistor and a second transistor;
a first electrode of the first transistor is connected to the gate of the driving transistor, and a second electrode of the first transistor is connected to a first initialization signal line;
a first electrode of the second transistor is connected to the gate of the driving transistor, and a second electrode of the second transistor is connected to the second electrode of the driving transistor;
the display panel further includes a second conductive layer, a second active layer and a third conductive layer;
the second conductive layer is located between the first conductive layer and the fifth conductive layer;
the second active layer is located between the second conductive layer and the fifth conductive layer, and the second active layer includes a first active portion, and a second active portion;
the first active portion is used to form a channel region of the first transistor; and
the second active portion is connected to the first active portion and used to form a channel region of the second transistor;
the third conductive layer is located between the second active layer and the fifth conductive layer, and the third conductive layer includes a first reset signal line, and a first gate line;
an orthographic projection of the first reset signal line on the base substrate covers an orthographic projection of the first active portion on the base substrate, and a partial structure of the first reset signal line is used to form a top gate of the first transistor; and
an orthographic projection of the first gate line on the base substrate covers an orthographic projection of the second active portion on the base substrate, and a partial structure of the first gate line is used to form a top gate of the second transistor;
in a same pixel driving circuit, the orthographic projection of the first gate line on the base substrate is located between the orthographic projection of the second conductive portion on the base substrate and the orthographic projection of the second gate line on the base substrate, and the orthographic projection of the first reset signal line on the base substrate is located at a side of the orthographic projection of the second gate line on the base substrate away from the orthographic projection of the second conductive portion on the base substrate.

In an example embodiment of the present disclosure, the second conductive layer includes the first initialization signal line, a third reset signal line and a third gate line;
an orthographic projection of the first initialization signal line on the base substrate is located at a side of the orthographic projection of the first reset signal line on the base substrate away from the orthographic projection of the second conductive portion on the base substrate;
the third reset signal line connected to the first reset signal line through a via hole, and an orthographic projection of third reset signal line on the base substrate covers the orthographic projection of the first active portion on the base substrate, and a partial structure of the three reset signal line is used to form a bottom gate of the first transistor; and
an orthographic projection of the third gate line on the base substrate covers the orthographic projection of the second active portion on the base substrate, and a partial structure of the third gate line is used to form a bottom gate of the second transistor.

In an example embodiment of the present disclosure, the pixel driving circuit further includes a fifth transistor, a first electrode of the fifth transistor is connected to the power line, and a second electrode of the fifth transistor is connected to a first electrode of the driving transistor, and a gate of the fifth transistor is connected to the enable signal line;
the first transistor and the second transistor are N-type transistors, the driving transistor, the fourth transistor, the fifth transistor, the sixth transistor, and the seventh transistor are P-type transistors.

In an example embodiment of the present disclosure, the display panel further includes a second conductive layer, a third conductive layer, and a fourth conductive layer:
the second conductive layer is located between the first conductive layer and the fifth conductive layer;
the third conductive layer is located between the second conductive layer and the fifth conductive layer; and
the fourth conductive layer is located between the third conductive layer and the fifth conductive layer, and the fourth conductive layer includes the second initialization signal line.

In an example embodiment of the present disclosure, the plurality of electrode portions include: a plurality of R electrode portions, a plurality of G electrode portions, and a plurality of B electrode portions;
the plurality of electrode portions are distributed in an array along a row direction and a column direction, the plurality of electrode portions include a first electrode column and a second electrode column that are distributed sequentially and alternately along the row direction, the first electrode column include an R electrode portion and a B electrode portion which are distributed sequentially and alternately along the column direction, and the second electrode column includes a plurality of G electrode portions spaced apart along the column direction; and
the plurality of electrode portions include a first electrode row and a second electrode row which are distributed sequentially and alternately in the column direction, the first electrode row includes an R electrode portion and a B electrode portion which are distributed sequentially and alternately along the row direction, and the second electrode row includes a plurality of G electrode portions spaced apart along the row direction.

In an example embodiment of the present disclosure, an overlapping area between an orthographic projection of an R electrode portion on the base substrate and the orthographic projection of the power line on the base substrate is S10, an area of an orthographic projection of a body portion of the R electrode portion on the base substrate is S11, and S10/S11 is larger than or equal to 1.1 and less than or equal to 2;
an overlapping area between an orthographic projection of a G electrode portion on the base substrate and the orthographic projection of the power line on the base substrate is S12, an area of an orthographic projection of a body portion of the G electrode portion on the base substrate is S13, and S12/S13 is larger than or equal to 0.2 and less than or equal to 1; and
an overlapping area between an orthographic projection of a B electrode portion on the base substrate and the orthographic projection of the power line on the base substrate is S14, an area of an orthographic projection of a body portion of the B electrode portion on the base substrate is S15, and S14/S15 is larger than or equal to 0.8 and less than or equal to 1.5.

In an example embodiment of the present disclosure, an area of an orthographic projection of a body portion of an R electrode portion on the base substrate is S11, an overlapping area between an orthographic projection of a supplemental portion of the R electrode portion on the base substrate and the orthographic projection of the power line on the base substrate is S16, and S16/S11 is larger than or equal to 0.2 and less than or equal to 1.1;
an area of an orthographic projection of a body portion of a G electrode portion on the base substrate is S13, an overlapping area between an orthographic projection of a supplemental portion of the G electrode portion on the base substrate and the orthographic projection of the power line on the base substrate is S17, and S17/S13 is larger than or equal to 0.15 and less than or equal to 0.95; and
an area of an orthographic projection of a body portion of a B electrode portion on the base substrate is S15, an overlapping area between an orthographic projection of a supplemental portion of the B electrode portion on the base substrate and the orthographic projection of the power line on the base substrate is S18, and S18/S15 is larger than or equal to 0.05 and less than or equal to 0.4.

In an example embodiment of the present disclosure, the display panel includes a plurality of repetition units distributed along the row direction and the column direction, each of the repetition units includes two pixel driving circuits, the two pixel driving circuits includes a first pixel driving circuit and a second pixel driving circuit which are distributed along the row direction, and the first pixel driving circuit and the second pixel driving circuit are arranged in mirror symmetry;
the pixel driving circuit includes a driving transistor, a fourth transistor and a fifth transistor;
a first electrode of the fourth transistor is connected to a data line, and a second electrode of the fourth transistor is connected to a first electrode of the driving transistor;
a first electrode of the fifth transistor is connected to the power line, and a second electrode of the fifth transistor is connected to the first electrode of the driving transistor;
the orthographic projection of the power line on the base substrate and an orthographic projection of the data line on the base substrate both extend along the column direction, and pixel driving circuits of each column are provided with one corresponding power line and one corresponding data line;
the power line includes: a first extension portion, a second extension portion and a third extension portion, and the second extension portion is connected between the first extension portion and the third extension portion;
a size of an orthographic projection of the second extension portion on the base substrate in the row direction is larger than a size of an orthographic projection of the first extension portion on the base substrate in the row direction, and the size of the orthographic projection of the second extension portion on the base substrate in the row direction is larger than a size of an orthographic projection of the third extension portion on the base substrate in the row direction;
in a same repetition unit, orthographic projections of two data lines on the base substrate are located between orthographic projections of two power lines on the base substrate;
in repetition units adjacent in the row direction, second extension portions of adjacent power lines are connected;
an orthographic projection of an R electrode portion on the base substrate overlaps with orthographic projections of two connected second extension portions on the base substrate, an orthographic projection of a B electrode portion on the base substrate overlaps with orthographic projections of two connected second extension portions on the base substrate, and an orthographic projection of a G electrode portion on the base substrate overlaps with orthographic projections of two data lines in the same repetition unit on the base substrate.

According to an aspect of the present disclosure, there is provided a display apparatus including the display panel as described above.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the specification, illustrate embodiments consistent with the present disclosure and together with the specification serve to explain the principles of the present disclosure. Apparently, the drawings in the following description are only some embodiments of the present disclosure, and those skilled in the art may obtain other drawings according to these drawings without creative efforts.

FIG. 1 is a schematic circuit structure diagram of a pixel driving circuit in related art;

FIG. 2 is a timing diagram of nodes in a driving method of a pixel driving circuit shown in FIG. 1;

FIG. 3 is a structural layout of a display panel according to an example embodiment of the present disclosure;

FIG. 4 is a structural layout of a fifth conductive layer in FIG. 3;

FIG. 5 is a structural layout of an electrode layer in FIG. 3;

FIG. 6 is a simulated change curve of a gate-drain voltage of a driving transistor under different gray levels;

FIG. 7 is a structural layout of a display panel in another example embodiment of the present disclosure;

FIG. 8 is a structural layout of a light-shielding layer in FIG. 7;

FIG. 9 is a structural layout of a first active layer in FIG. 7;

FIG. 10 is a structural layout of a first conductive layer in FIG. 7;

FIG. 11 is a structural layout of a second conductive layer in FIG. 7;

FIG. 12 is a structural layout of a second active layer in FIG. 7;

FIG. 13 is a structural layout of a third conductive layer in FIG. 7;

FIG. 14 is a structural layout of a fourth conductive layer in FIG. 7;

FIG. 15 is a structural layout of a fifth conductive layer in FIG. 7;

FIG. 16 is a structural layout of the light-shielding layer and the first active layer in FIG. 7;

FIG. 17 is a structural layout of the light-shielding layer, the first active layer, and the first conductive layer in FIG. 7;

FIG. 18 is a structural layout of the light-shielding layer, the first active layer, the first conductive layer, and the second conductive layer in FIG. 7;

FIG. 19 is a structural layout of the light-shielding layer, the first active layer, the first conductive layer, the second conductive layer, and the second active layer in FIG. 7;

FIG. 20 is a structural layout of the light-shielding layer, the first active layer, the first conductive layer, the second conductive layer, the second active layer and the third conductive layer in FIG. 7;

FIG. 21 is a structural layout of the light-shielding layer, the first active layer, the first conductive layer, the second conductive layer, the second active layer, the third conductive layer and the fourth conductive layer in FIG. 7;

FIG. 22 is a structural layout of the light-shielding layer, the first active layer, the first conductive layer, the second conductive layer, the second active layer, the third conductive layer, the fourth conductive layer and the fifth conductive layer in FIG. 7;

FIG. 23 is an actual measured timing diagram of a data signal terminal and a first power terminal of a pixel driving circuit in related art;

FIG. 24 is a display state diagram of a display panel presenting a specific screen in related art;

FIG. 25 is a partial cross-sectional view of the display panel taken along a dotted line AA in FIG. 7;

FIG. 26 is a structural layout of a display panel in another example embodiment of the present disclosure;

FIG. 27 is a structural layout of a fifth conductive layer and an electrode layer in FIG. 26;

FIG. 28 is a structural layout of the fifth conductive layer in FIG. 26;

FIG. 29 is a structural layout of the electrode layer in FIG. 26;

FIG. 30 is a partial cross-sectional view taken along a dotted line BB in FIG. 26.

### DETAILED DESCRIPTION

Example embodiments will now be described more fully with reference to the accompanying drawings. Example embodiments may, however, be embodied in many forms and should not be construed as being limited to the examples set forth herein; rather, these embodiments are provided so that the present disclosure will be thorough and complete, and will fully convey the concept of example embodiments to those skilled in the art. The same reference numerals in the drawings denote the same or similar structures, and thus their repeated descriptions will be omitted.

Terms “one”, “a/an”, and “the/said” are used to indicate presence of one or more elements/components/etc.; terms “comprising/comprises/comprise” and “having/has/have” are used to indicate an open-ended inclusive, and mean that there may be additional elements/components/etc. in addition to the listed elements/components/etc.

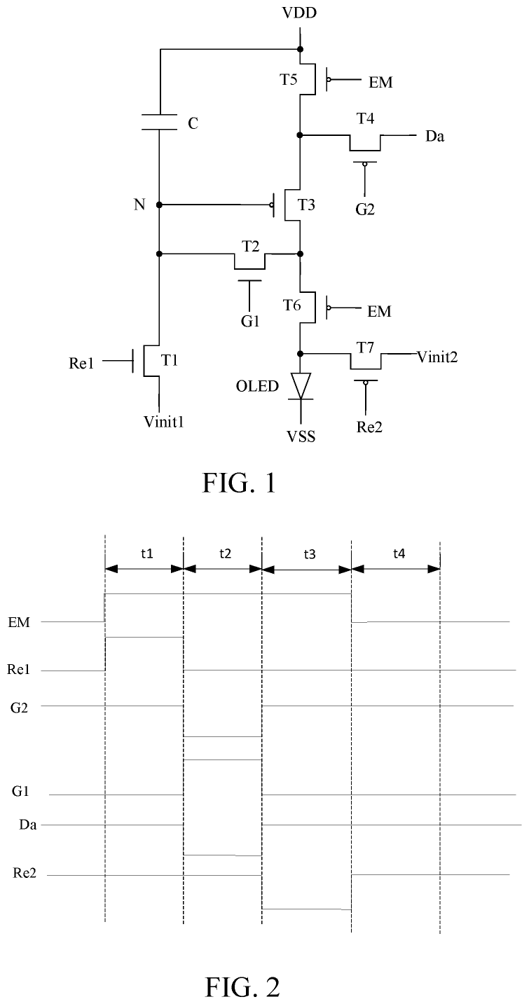

FIG. 1 is a schematic circuit structure diagram of a pixel driving circuit in related art. The pixel driving circuit may include: a driving transistor T3, a first transistor T1, a second transistor T2, a fourth transistor T4, a fifth transistor T5, a sixth transistor T6, a seventh transistor T7, and a capacitor C. A first electrode of the fourth transistor T4 is connected to a data signal terminal Da, a second electrode of the fourth transistor T4 is connected to a first electrode of the driving transistor T3, and a gate of the fourth transistor T4 is connected to a second gate driving signal terminal G2. A first electrode of the fifth transistor T5 is connected to a first power terminal VDD, a second electrode of the fifth transistor T5 is connected to the first electrode of the driving transistor T3, and a gate of the fifth transistor T5 is connected to an enable signal terminal EM. A gate of the driving transistor T3 is connected to a node N. A first electrode of the second transistor T2 is connected to the node N, a second electrode of the second transistor T2 is connected to a second electrode of the driving transistor T3, and a gate of the second transistor T2 is connected to a first gate driving signal terminal G1. A first electrode of the sixth transistor T6 is connected to the second electrode of the driving transistor T3, a second electrode of the sixth transistor T6 is connected to a first electrode of the seventh transistor T7, and a gate of the sixth transistor T6 is connected to the enable signal terminal EM. A second electrode of the seventh transistor T7 is connected to a second initialization signal terminal Vinit2, and a gate of the seventh transistor T7 is connected to a second reset signal terminal Re2. A first electrode of the first transistor T1 is connected to the node N, a second first electrode of the first transistor T1 is connected to a first initialization signal terminal Vinit1, and a gate of the first transistor T1 is connected to a first reset signal terminal Re1. A first electrode of the capacitor C is connected to the node N, and a second electrode of the capacitor C is connected to the first power terminal VDD. The pixel driving circuit may be connected to a light-emitting unit OLED for driving the light-emitting unit OLED to emit light. The light-emitting unit OLED may be connected between the second electrode of the sixth transistor T6 and a second power terminal VSS. The first transistor T1 and the second transistor T2 may be N-type transistors. For example, the first transistor T1 and the second transistor T2 may be N-type metal oxide transistors. N-type metal oxide transistors have relatively small leakage current, and thus electricity leakage by the node N through the first transistor T1 and the second transistor T2 in a light-emitting stage can be avoided. At the same time, the driving transistor T3, the fourth transistor T4, the fifth transistor T5, the sixth transistor T6, and the seventh transistor T7 may be P-type transistors. For example, the driving transistor T3, the fourth transistor T4, the fifth transistor T5, and the sixth transistor T6 and the seventh transistor T7 may be P-type low-temperature poly-silicon transistors. P-type low-temperature poly-silicon transistors have relatively high carrier mobility, which is conducive to achieving a display panel with high resolution, high response speed, high pixel density, and high aperture ratio. The first initialization signal terminal and the second initialization signal terminal may output the same or different voltage signals according to actual conditions.

FIG. 2 is a timing diagram of nodes in a driving method of the pixel driving circuit in FIG. 1. In this figure, G1 represents the timing of the first gate driving signal terminal G1, G2 represents the timing of the second gate driving signal terminal G2, Re1 represents the timing of the first reset signal terminal Re1, Re2 represents the timing of the second reset signal terminal Re2, EM represents the timing of the enable signal terminal EM, and Da represents the timing of the data signal terminal Da. The driving method of the pixel driving circuit may include a first reset stage t1, a compensation stage t2, a second reset stage t3, and a light-emitting stage t4. In the first reset stage t1: the first reset signal terminal Re1 outputs a high-level signal, the first transistor T1 is turned on, and the first initialization signal terminal Vinit1 inputs an initialization signal to the node N. In the compensation stage t2: the first gate driving signal terminal G1 outputs a high-level signal, the second gate driving signal terminal G2 outputs a low-level signal, the fourth transistor T4 and the second transistor T2 are turned on, and at the same time, the data signal terminal Da outputs a driving signal to write a voltage Vdata+Vth (that is, the sum of the voltages Vdata and Vth) to the node N, where Vdata is the voltage of the driving signal, and Vth is the threshold voltage of the driving transistor T3. In the second reset stage t3: the second reset signal terminal Re2 outputs a low-level signal, the seventh transistor T7 is turned on, and the second initialization signal terminal Vinit2 inputs an initialization signal to the second electrode of the sixth transistor T6. In the light-emitting stage t4: the enable signal terminal EM outputs a low-level signal, the sixth transistor T6 and the fifth transistor T5 are turned on, and the driving transistor T3 causes light to be emitted under the action of the voltage Vdata+Vth stored in the capacitor C.

The output current formula of the driving transistor is as follows:

I=(μWCox/2L)(Vgs−Vth)²

where I is the output current of the driving transistor; μ is the carrier mobility; Cox is the gate capacitance per unit area, W is the width of the channel of the driving transistor, L is the length of the channel of the driving transistor, Vgs is the gate-source voltage difference of the driving transistor, and Vth is the threshold voltage of the driving transistor.

According to the above output current formula of the driving transistor, by bringing the gate voltage Vdata+Vth and the source voltage Vdd of the driving transistor in the pixel driving circuit of the present disclosure into the above formula, the following can be obtained: the output current of the driving transistor in the pixel driving circuit of the present disclosure I=(μWCox/2L)(Vdata+Vth−Vdd−Vth)². The pixel driving circuit can avoid the influence of the driving transistor threshold on its output current.

However, due to the hysteresis phenomenon of the driving transistor T3, especially in low-frequency display, the hysteresis phenomenon of the driving transistor is more obvious. The hysteresis phenomenon of the driving transistor may cause that the output current of the driving transistor in an early stage of the light-emitting stage of the pixel driving circuit cannot reach a driving current required by a target gray level, and thus this may cause a flicker phenomenon in the display panel.

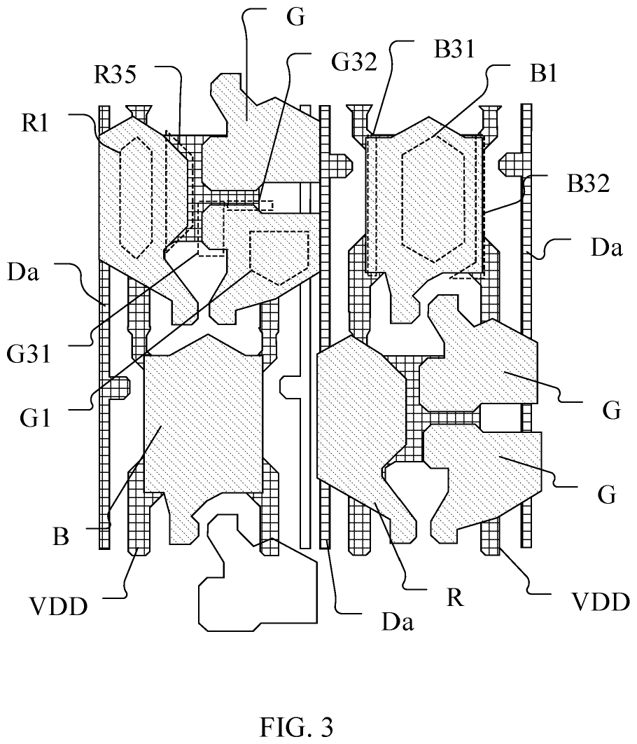

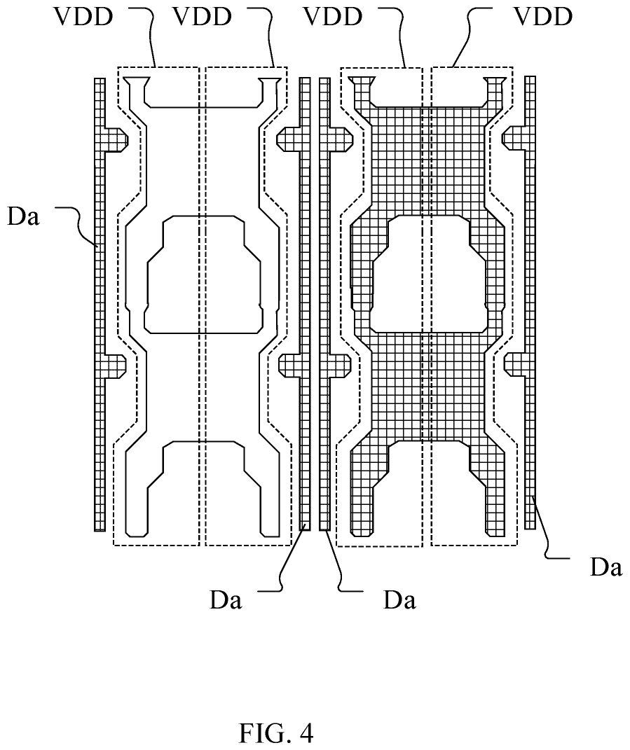

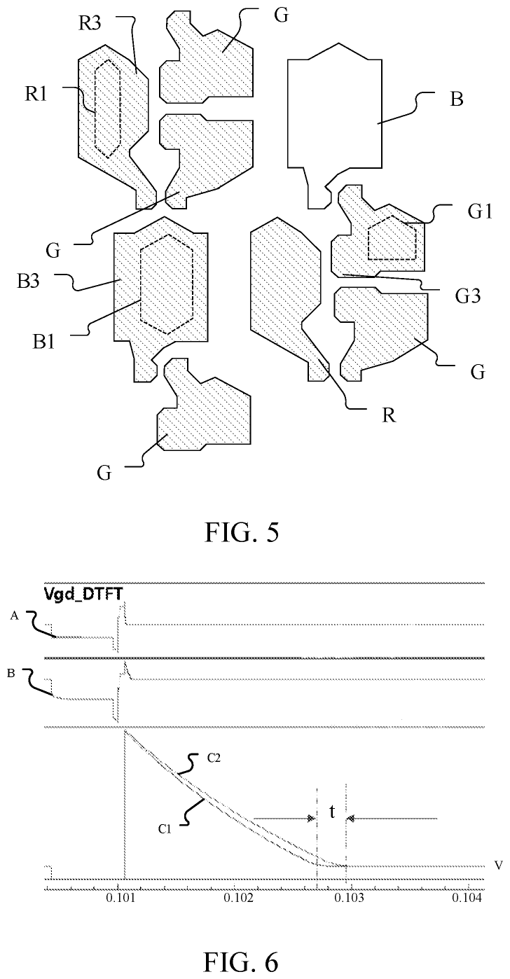

In view of the above, an example embodiment provides a display panel, which may include a base substrate, a fifth conductive layer, an electrode layer, and a pixel defining layer, as shown in FIG. 3 to FIG. 5. FIG. 3 is a structural layout of a display panel according to an example embodiment of the present disclosure. FIG. 4 is a structural layout of the fifth conductive layer in FIG. 3. FIG. 5 is a structural layout of the electrode layer in FIG. 3. The fifth conductive layer is located on a side of the base substrate, and the fifth conductive layer includes a power line VDD. The electrode layer is located on a side of the fifth conductive layer away from the base substrate, and the electrode layer includes an R electrode portion R, a G electrode portion G, and a B electrode portion B. The R electrode portion R includes a body portion R1 and a supplemental portion R3 which are connected with each other. The G electrode portion G includes a body portion G1 and a supplemental portion G3 which are connected with each other. The B electrode portion B includes a body portion B1 and a supplemental portion B3 which are connected with each other. An orthographic projection of a supplemental portion of each electrode portion on the base substrate at least partially overlaps with an orthographic projection of a power line VDD on the base substrate. The pixel defining layer is located on a side of the electrode layer away from the base substrate. The pixel defining layer includes a plurality of pixel openings (not shown). The plurality of pixel openings are arranged in one-to-one correspondence with the plurality of electrode portions. An orthographic projection of a pixel opening on the base substrate overlaps with an orthographic projection of a body portion of an electrode portion corresponding to the pixel opening on the base substrate. A pixel opening is used to form a light-emitting unit therein, and a supplemental portion of an electrode portion may refer to all structure(s) in the electrode portion except the body portion.

This example embodiment increases an overlapping area between an electrode portion and a power line VDD by arranging a supplemental portion in the electrode portion, thereby increasing the capacitance of the electrode portion itself of a light-emitting unit, and accordingly extending the charging time before the light-emitting unit emits light. In this example embodiment, a period of time when the current output of the driving transistor is unstable may be completely located or at least partially located in the charging period of the light-emitting unit. That is, this setting can reduce a duration in which the light-emitting unit emits light during the period of time when the current output of the driving transistor is unstable. Thus, the setting can improve the flicker problem of the display panel.

FIG. 6 is a simulated change curve of a gate-drain voltage of a driving transistor under different gray levels. In this figure, A represents a change curve of the gate-drain voltage of the driving transistor with time under a high gray level, B represents a change curve of the gate-drain voltage of the driving transistor with time under a medium gray level, C1 represents a change curve of the gate-drain voltage of the driving transistor with time under a low gray level when the capacitance of the electrode portion of the light-emitting unit is 0, and C2 represents a change curve of the gate-drain voltage of the driving transistor with time under a low gray level when the capacitance of the electrode portion of the light-emitting unit is 13. As can be seen from FIG. 6, under a low gray level, when the capacitance of the electrode portion of the light-emitting unit increases, the gate-drain voltage of the driving transistor will delay for a period of time t before reaching a voltage V that can normally drive the light-emitting unit to emit light. That is, this simulation diagram can illustrate that by increasing the capacitance of the electrode of light-emitting unit, the charging time of the light-emitting unit can be extended.

In an example embodiment, as shown in FIG. 3 to FIG. 5, the pixel units in the display panel may be in a GGRB distribution. That is, an R electrode portion R, G electrode portion(s) G, and a B electrode portion B may be distributed alternately along a same electrode row. In the same electrode row, two G electrode portions G distributed along a column direction are provided between the R electrode portion R and the B electrode portion B. In adjacent electrode rows, electrode portions of the same color are located in different columns. In two electrode rows separated by one electrode row, electrode portions of the same color are located in the same column. The R electrode portion may be an anode of a red light-emitting unit, the G electrode portion may be an anode of a green light-emitting unit, and the B electrode portion may be an anode of the blue light-emitting unit. It should be understood that in other example embodiments, the pixel units of the display panel may also be distributed in other ways, such as real RGB distribution, etc.

In an example embodiment, the pixel driving circuit in the display panel may be as shown in FIG. 1. It should be understood that in other example embodiments, the pixel driving circuit in the display panel may also have other structures. As long as the display panel has the flicker problem caused by the hysteresis of the driving transistor, the above structure can be used to improve the flicker.

In an example embodiment, as shown in FIG. 3 to FIG. 5, an overlapping area between an orthographic projection of an R electrode portion R on the base substrate and an orthographic projection of a power line VDD on the base substrate is S1, an area of an orthographic projection of a body portion R1 of the R electrode portion on the base substrate is S2, and S1/S2 may be larger than or equal to 0.8 and less than or equal to 1.9. For example, S1/S2 may be equal to 0.8, 0.9, 1, 1.1, 1.2, 1.3, 1.4, 1.5, 1.6, 1.7, 1.8, or 1.9, etc.

In an example embodiment, as shown in FIG. 3 to FIG. 5, an overlapping area between an orthographic projection of a G electrode portion G on the base substrate and an orthographic projection of a power line VDD on the base substrate is S3, an area of an orthographic projection of a body portion G1 of the G electrode portion on the base substrate is S4, and S3/S4 may be larger than or equal to 1 and less than or equal to 1.7. For example, S3/S4 may be equal to 1, 1.1, 1.2, 1.3, 1.4, 1.5, 1.6, or 1.7, etc.

In an example embodiment, as shown in FIG. 3 to FIG. 5, an overlapping area between an orthographic projection of a B electrode portion B on the base substrate and an orthographic projection of a power line on the base substrate is S5, an area of an orthographic projection of a body portion B1 of the B electrode portion on the base substrate is S6, and S5/S6 may be larger than or equal to 1.6 and less than or equal to 2. For example, S5/S6 may be equal to 1.6, 1.7, 1.8, 1.9, or 2, etc.

In an example embodiment, as shown in FIG. 3 to FIG. 5, a supplemental portion of an R electrode includes a fifth supplemental portion R35. In an R electrode portion R and a G electrode portion G located in the same row and adjacent columns, an orthographic projection of the fifth supplemental portion R35 of the R electrode portion R on the base substrate is located on a side of an orthographic projection of the body portion R1 of the R electrode portion on the base substrate facing the orthographic projection of the G electrode portion G. The area of the orthographic projection of the body portion R1 of the R electrode portion on the base substrate is S2, an overlapping area between the orthographic projection of the supplemental portion R3 of the R electrode portion on the base substrate and an orthographic projection of a power line on the base substrate is S7, and S7/S2 may be larger than or equal to 0.04 and less than or equal to 1.14. For example, S7/S2 may be equal to 0.04, 0.1, 0.2, 0.3, 0.4, 0.5, 0.6, 0.7, 0.8, 0.9, 1, 1.1, or 1.14.

In an example embodiment, as shown in FIG. 3 to FIG. 5, a supplemental portion G3 of a G electrode portion may include a first supplemental portion G31 and a second supplemental portion G32. In an R electrode portion and a G electrode portion located in a same row and adjacent columns, an orthographic projection of the first supplemental portion G31 of the G electrode portion on the base substrate is located on a side of an orthographic projection of the body portion G1 of the G electrode portion on the base substrate facing an orthographic projection of the R electrode portion R on the base substrate; an orthographic projection of the second supplemental portion G32 of the G electrode portion on the base substrate is located on a side of the orthographic projection of the body portion G1 of the G electrode portion on the base substrate facing an orthographic projection of another G electrode portion on the base substrate. An area of the orthographic projection of the body portion G1 of the G electrode portion on the base substrate is S4, an overlapping area between the orthographic projection of the supplemental portion G3 of the G electrode portion on the base substrate and an orthographic projection of a power line on the base substrate is S8, and S8/S4 may be larger than or equal to 0.1 and less than or equal to 0.8. For example, S8/S4 may be equal to 0.1, 0.2, 0.3, 0.4, 0.5, 0.6, 0.7, or 0.8, etc.

In an example embodiment, as shown in FIG. 3 to FIG. 5, a supplemental portion of a B electrode portion may include a third supplemental portion B31 and a fourth supplemental portion B32. In a B electrode portion and a G electrode portion located in the same row and adjacent columns, an orthographic projection of the third supplemental portion B31 of the B electrode portion on the base substrate is located on a side of an orthographic projection of the body portion B1 of the B electrode portion on the base substrate facing an orthographic projection of the G electrode portion on the base substrate; an orthographic projection of the fourth supplemental portion B32 of the B electrode portion on the base substrate is located on a side of the orthographic projection of the body portion B1 of the B electrode portion on the base substrate away from the orthographic projection of the third supplemental portion B31 of the B electrode portion on the base substrate. An area of the orthographic projection of the body portion B1 of the B electrode portion on the base substrate is S6, an overlapping area between the orthographic projection of the supplemental portion of the B electrode portion on the base substrate and an orthographic projection of a power line on the base substrate is S9, and S9/S6 is larger than or equal to 0.1 and less than or equal to 0.5. For example, S9/S6 may be equal to 0.1, 0.2, 0.3, 0.4, or 0.5, etc.

In an example embodiment, S5 may be larger than S1, and S1 may be larger than S3. S5/S1 may be larger than or equal to 1.2 and less than or equal to 3. For example, S5/S1 may be equal to 1.2, 1.5, 2, 2.2, 2.5, 2.7, 3, etc. S1/S3 may be larger than or equal to 1.1 and less than or equal to 2. For example, S1/S3 may be equal to 1.1, 1.3, 1.5, 1.7, or 2, etc.

As shown in FIG. 3 to FIG. 5, the fifth conductive layer may further include a data line Da. The data line Da may be used to provide the data signal terminal in FIG. 1. An overlapping area between an orthographic projection of an R electrode portion on the base substrate and an orthographic projection of a data line Da on the base substrate may be larger than an overlapping area between an orthographic projection of a G electrode portion on the base substrate and an orthographic projection of a data line Da on the base substrate. An overlapping area between an orthographic projection of a G electrode portion on the base substrate and an orthographic projection of a data line Da on the base substrate may be larger than an overlapping area between an orthographic projection of a B electrode portion on the base substrate and an orthographic projection of a data line Da on the base substrate. The orthographic projection of a B electrode portion on the base substrate may not overlap with the orthographic projection of a data line Da on the base substrate.

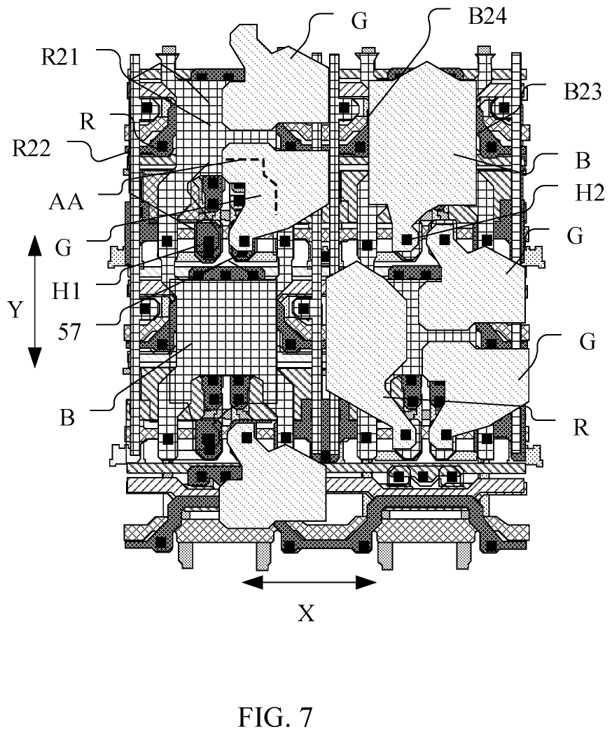

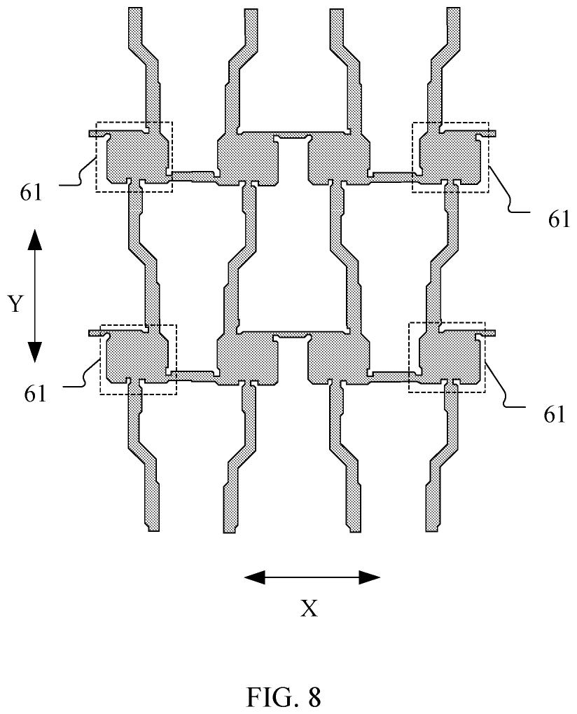

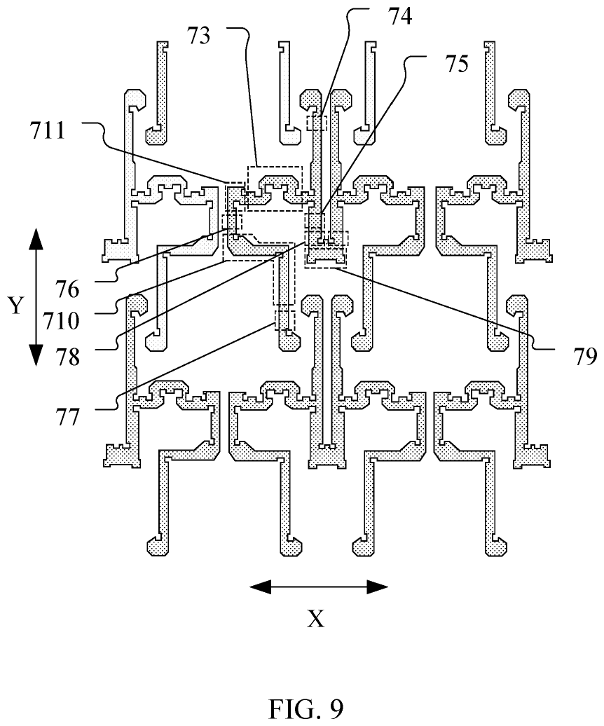

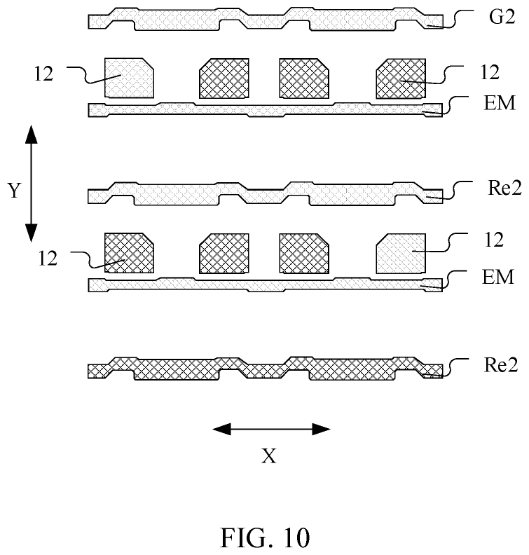

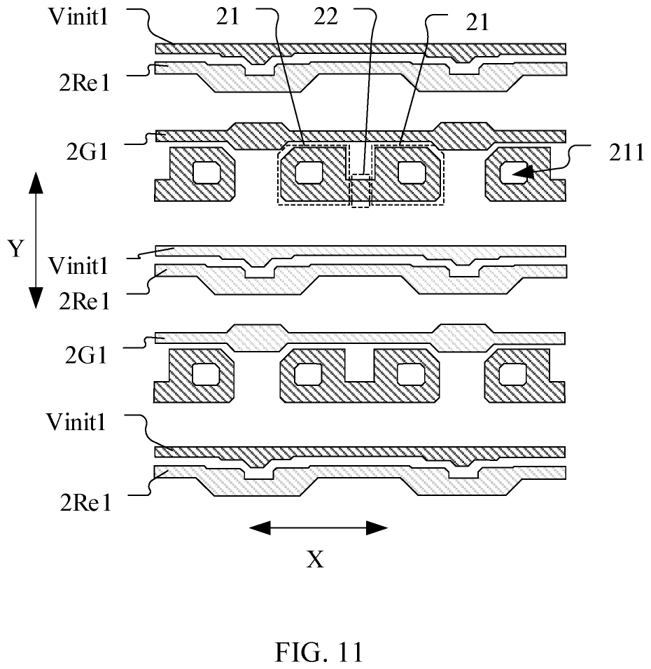

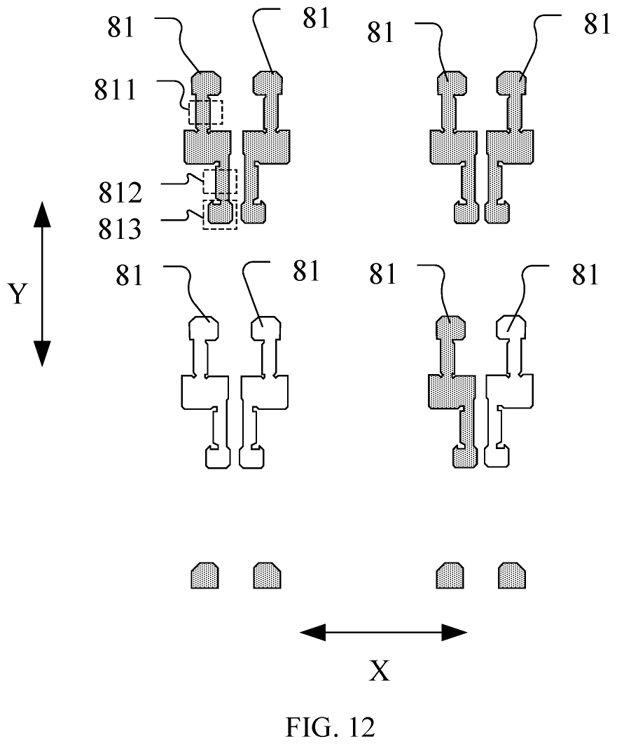

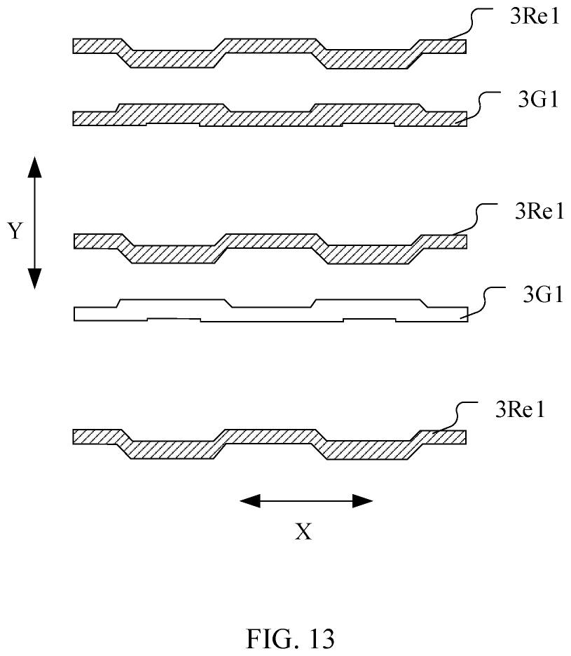

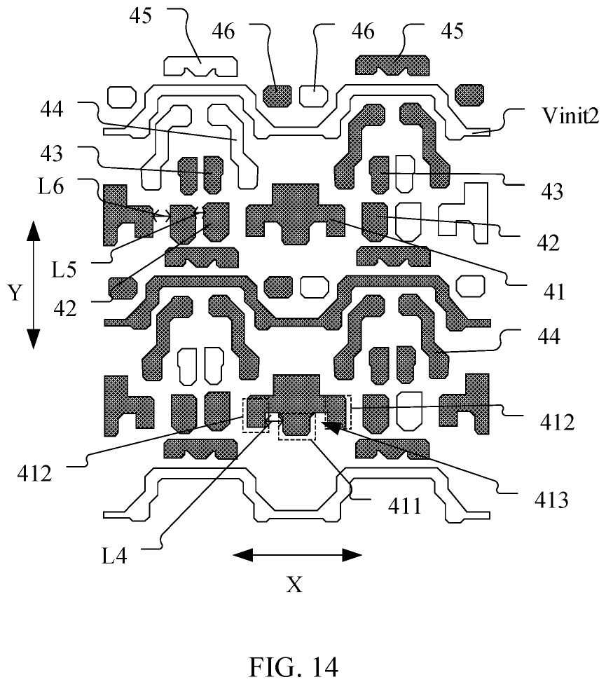

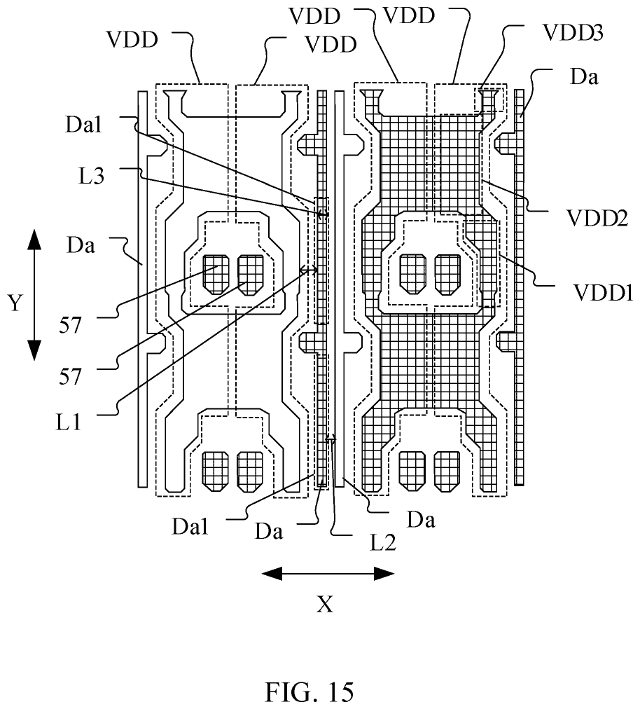

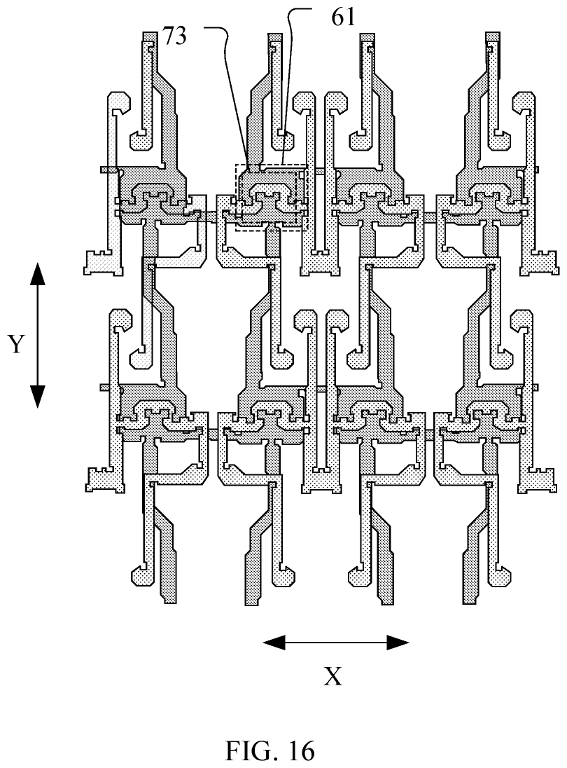

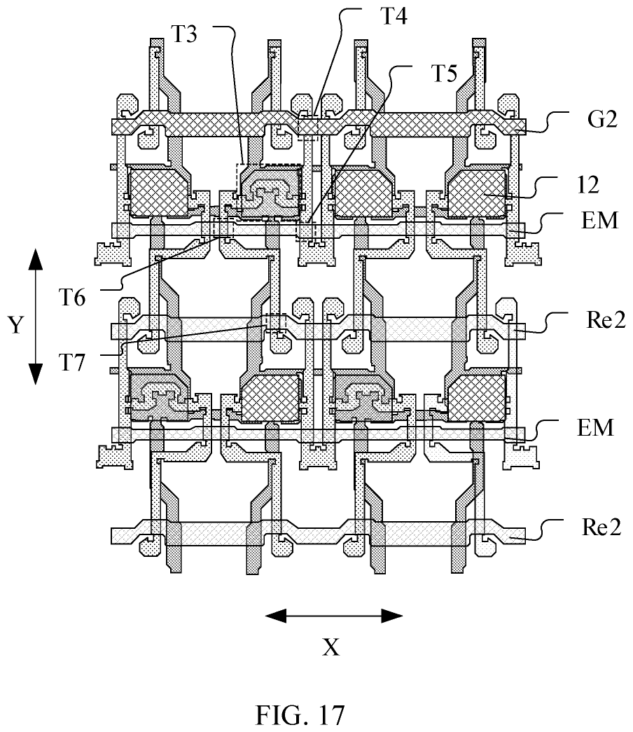

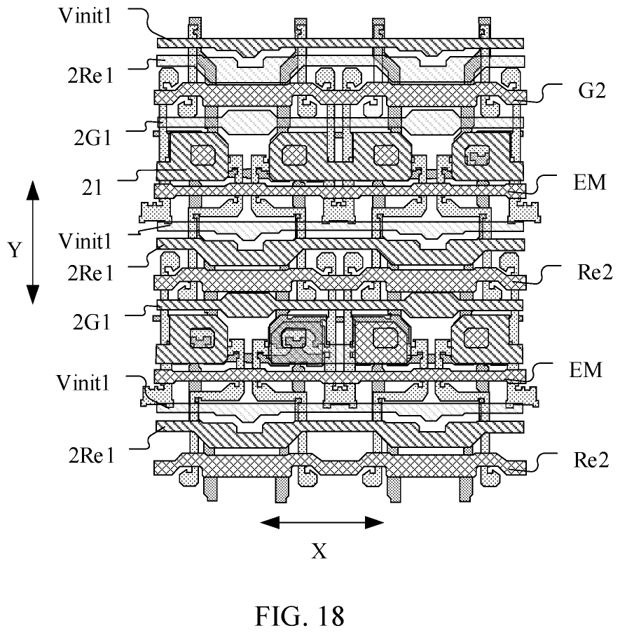

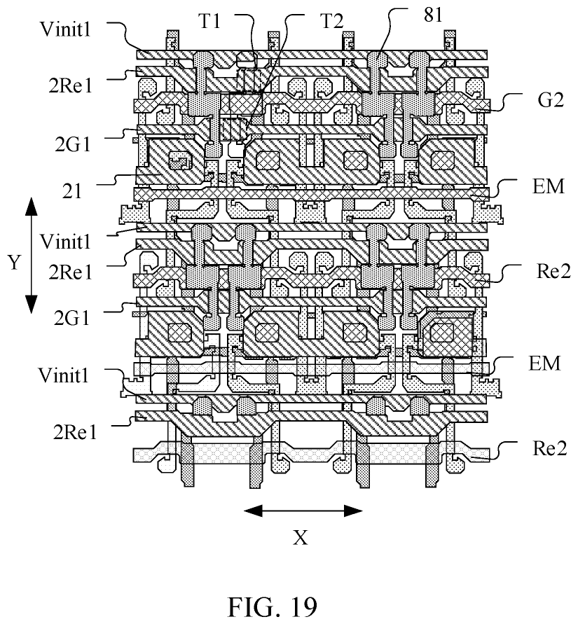

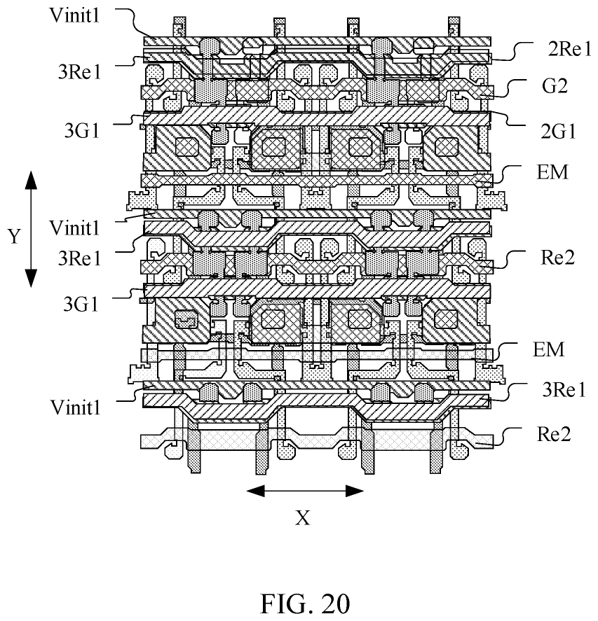

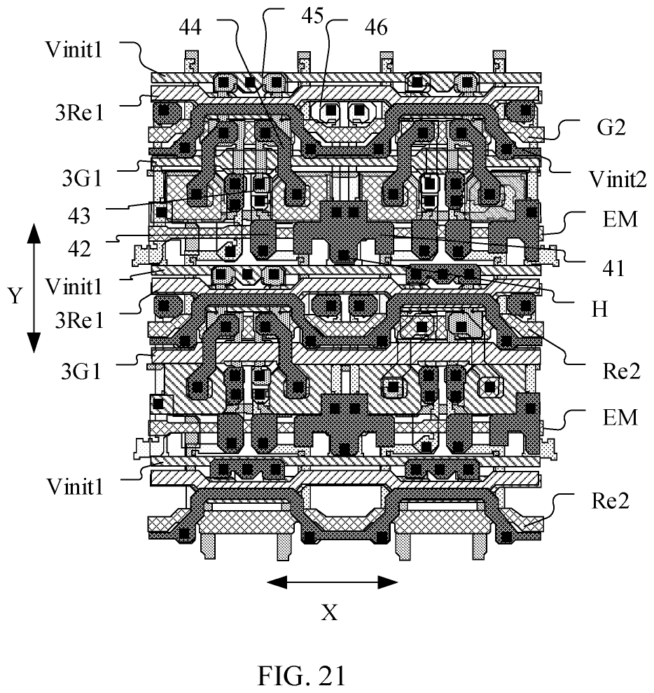

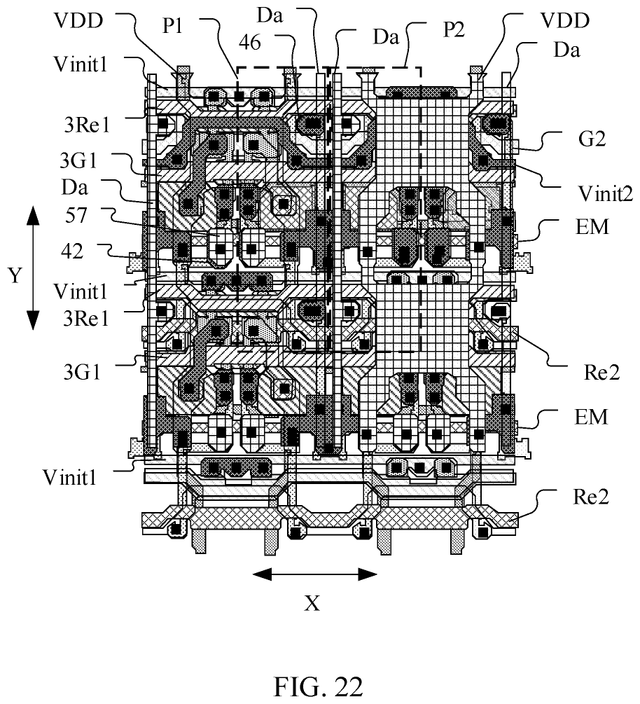

An example embodiment further provides another display panel. The display panel may include a base substrate, a light-shielding layer, a first active layer, a first conductive layer, a second conductive layer, a second active layer, a third conductive layer, a fourth conductive layer, a fifth conductive layer, and an electrode layer which are sequentially stacked. An insulating layer may be provided between the above layers. As shown in FIG. 7 to FIG. 22, FIG. 7 is a structural layout of a display panel according to another example embodiment of the present disclosure. FIG. 8 is a structural layout of the light-shielding layer in FIG. 7. FIG. 9 is a structural layout of the first active layer in FIG. 7. FIG. 10 is a structural layout of the first conductive layer in FIG. 7. FIG. 11 is a structural layout of the second conductive layer in FIG. 7. FIG. 12 is a structural layout of the second active layer in FIG. 7. FIG. 13 is a structural layout of the third conductive layer in FIG. 7. FIG. 14 is a structural layout of the fourth conductive layer in FIG. 7. FIG. 15 is a structural layout of the fifth conductive layer in FIG. 7. FIG. 16 is a structural layout of the light-shielding layer and the first active layer in FIG. 7. FIG. 17 is a structural layout of the light-shielding layer, the first active layer and the first conductive layer in FIG. 7. FIG. 18 is a structural layout of the light-shielding layer, the first active layer, the first conductive layer, and the second conductive layer in FIG. 7. FIG. 19 is a structural layout of the light-shielding layer, the first active layer, the first conductive layer, the second conductive layer, and the second active layer in FIG. 7. FIG. 20 is a structural layout of the light-shielding layer, the first active layer, the first conductive layer, the second conductive layer, the second active layer and the third conductive layer in FIG. 7. FIG. 21 is a structural layout of the light-shielding layer, the first active layer, the first active layer, the first conductive layer, the second conductive layer, the second active layer, the third conductive layer, and the fourth conductive layer in FIG. 7. FIG. 22 is a structural layout of the light-shielding layer, the first active layer, the first conductive layer, the second conductive layer, the second active layer, the third conductive layer, the fourth conductive layer, and the fifth conductive layer in FIG. 7. The display panel may include a plurality of pixel driving circuits shown in FIG. 1. As shown in FIG. 22, the plurality of pixel driving circuits may include a first pixel driving circuit P1 and a second pixel driving circuit P2 adjacently distributed in a row direction X. The first pixel driving circuit P1 and the second pixel driving circuit P2 may be arranged in mirror symmetry. The first pixel driving circuit P1 and the second pixel driving circuit P2 may form a repetition unit. The display panel may include a plurality of repetition units distributed in an array in the row direction X and the column direction Y. In addition, the display panel may include all structures of the display panel shown in FIG. 3.

As shown in FIGS. 7, 8, and 16, the light-shielding layer may include a plurality of light-shielding portions 61 distributed in the row direction X and the column direction Y. Adjacent light-shielding portions may be connected to each other. The light-shielding layer may be a conductor structure, for example, the light-shielding layer may be a light-shielding metal layer.

As shown in FIGS. 7, 9 and 17, the first active layer may include a third active portion 73, a fourth active portion 74, a fifth active portion 75, a sixth active portion 76, a seventh active portion 77, an eighth active portion 78, a ninth active portion 79, a tenth active portion 710, and an eleventh active portion 711. Among them, the third active portion 73 may be used to form a channel region of the driving transistor T3; the fourth active portion 74 may be used to form a channel region of the fourth transistor T4; the fifth active portion 75 may be used to form a channel region of the fifth transistor T5; the sixth active portion 76 may be used to form a channel region of the sixth transistor T6; the seventh active portion 77 may be used to form a channel region of the seventh transistor T7; the eighth active portion 78 is connected to a side of the fifth active portion 75 away from the third active portion 73, and the ninth active portion 79 is connected between an eighth active portion 78 in the first pixel driving circuit P1 and an eighth active portion 78 in the second pixel driving circuit P2. The tenth active portion 710 is connected between the sixth active portion 76 and the seventh active portion 77, and the eleventh active portion 711 is connected between the sixth active portion 76 and the third active portion 73. The eighth active portion 78 may be used to form the first electrode of the fifth transistor. In this example embodiment, the eighth active portions in two adjacent pixel driving circuits are connected through the ninth active portion 79, thereby reducing a voltage difference between the first power terminals in adjacent pixel driving circuits. As shown in FIG. 16, an orthographic projection of the light-shielding portion 61 on the base substrate may cover an orthographic projection of the third active portion 73 on the base substrate. The light-shielding portion 61 can reduce the impact of light on the characteristics of the driving transistor. The first active layer may be formed of poly-silicon material. Correspondingly, the driving transistor T3, the fourth transistor T4, the fifth transistor T5, the sixth transistor T6, and the seventh transistor T7 may be P-type low-temperature poly-silicon thin film transistors.

As shown in FIGS. 7, 10, and 17, the first conductive layer may include: a second conductive portion 12, a second gate line G2, an enable signal line EM, and a second reset signal line Re2. The second gate line G2 may be used to provide the second gate driving signal terminal in FIG. 1. The enable signal line EM may be used to provide the enable signal terminal in FIG. 1. The second reset signal line Re2 may be used to provide the second reset signal terminal in FIG. 1. The orthographic projection of the second gate line G2 on the base substrate, the orthographic projection of the enable signal line EM on the base substrate, and the orthographic projection of the second reset signal line Re2 on the base substrate may all extend along the row direction X. In this example embodiment, an orthographic projection of a certain structure on the base substrate extending along a certain direction may be understood as: the orthographic projection of the structure on the base substrate extends straightly or in a bent manner along the direction. The orthographic projection of the second gate line G2 on the base substrate covers the orthographic projection of the fourth active portion 74 on the base substrate, and a partial structure of the second gate line G2 is used to form the gate of the fourth transistor. The orthographic projection of the enable signal line EM on the base substrate covers the orthographic projection of the fifth active portion 75 on the base substrate and the orthographic projection of the sixth active portion 76 on the base substrate. A partial structure of the enable signal line EM may be used to form the gates of the fifth transistor T5 and the sixth transistor T6 respectively. The orthographic projection of the second reset signal line Re2 on the base substrate may cover the orthographic projection of the seventh active portion 77 on the base substrate, and a partial structure of the second reset signal line Re2 may be used to form the gate of the seventh transistor T7. The orthographic projection of the second conductive portion 12 on the base substrate covers the orthographic projection of the third active portion 73 on the base substrate. The second conductive portion 12 may be used to form the gate of the driving transistor T3 and the first electrode of the capacitor. As shown in FIG. 17, the second gate line G2 in the pixel driving circuits of the current row can be reused as a second reset signal line Re2 in the pixel driving circuits of a preceding row. This arrangement can improve the integration level of the pixel driving circuits and reduce the layout area of the pixel driving circuits. The light-shielding layer may be connected to a stable power terminal. For example, the light-shielding layer may be connected to the first power terminal, the first initialization signal terminal, the second initialization signal terminal, etc. as shown in FIG. 1. The light-shielding portion 61 may play a role of voltage stabilization for the second conductive portion 12, thereby reducing the voltage fluctuation of the gate of the driving transistor T3 during the light-emitting stage. In addition, the display panel can use the first conductive layer as a mask to perform conductorization processing on the first active layer, that is, a region of the first active layer covered by the first conductive layer can form a channel region of a transistor, and a region of the first active layer not covered by the first conductive layer forms a conductor structure.

As shown in FIGS. 7, 11, and 18, the second conductive layer may include: a first initialization signal line Vinit1, a third reset signal line 2Re1, a third gate line 2G1, and a plurality of first conductive portions 21. Among them, the first initialization signal line Vinit1 is used to provide the first initialization signal terminal in FIG. 1, the third reset signal line 2Re1 may be used to provide the first reset signal terminal in FIG. 1, and the third gate line 2G1 may be used to provide the first gate driving signal terminal in FIG. 1. The orthographic projection of the first initialization signal line Vinit on the base substrate, the orthographic projection of the third reset signal line 2Re1 on the base substrate, and the orthographic projection of the third gate line 2G1 on the base substrate may all extend along the row direction X. As shown in FIG. 11, the second conductive layer may further include a plurality of first connection portions 22. In a same repetition unit, a first connection portion 22 is connected between two first conductive portions 21 which are adjacent in the row direction. Furthermore, in other example embodiments, in repetition units which are adjacent in the row direction, adjacent first conductive portions 21 may also be connected.

As shown in FIGS. 7, 12, and 19, the second active layer may include an active portion 81, and the active portion 81 may include a first active portion 811, a second active portion 812, and a twelfth active portion 813 which are connected with each other. The first active portion 811 may be used to form a channel region of the first transistor; the second active portion 812 may be used to form a channel region of the second transistor T2; the twelfth active portion 813 is connected to an end of the second active portion 812 away from the first active portion 811. The second active layer may be formed of indium gallium zinc oxide, and accordingly the first transistor T1 and the second transistor T2 may be N-type metal oxide thin film transistors. The orthographic projection of the third gate line 2G1 on the base substrate may cover the orthographic projection of the second active portion 812 on the base substrate, and a partial structure of the third gate line 2G1 may be used to form a bottom gate of the second transistor. The orthographic projection of the third reset signal line 2Re1 on the base substrate may cover the orthographic projection of the first active portion 811 on the base substrate, and a partial structure of the third reset signal line 2Re1 may be used to form a bottom gate of the first transistor T1.

As shown in FIGS. 7, 13, and 20, the third conductive layer may include a first reset signal line 3Re1 and a first gate line 3G1. Both the orthographic projection of the first reset signal line 3Re1 on the base substrate and the orthographic projection of the first gate line 3G1 on the base substrate may extend along the row direction X. The first reset signal line 3Re1 may be used to provide the first reset signal terminal in FIG. 1. The orthographic projection of the first reset signal line 3Re1 on the base substrate may cover the orthographic projection of the first active portion 8 to 11 on the base substrate. A partial structure of the first reset signal line 3Re1 may be used to form a top gate of the first transistor T1. At the same time, the first reset signal line 3Re1 may be connected to the third reset signal line 2Re1 through a via hole located in an edge wiring region of the display panel. The first gate line 3G1 may be used to provide the first gate driving signal terminal in FIG. 1. The orthographic projection of the first gate line 3G1 on the base substrate may cover the orthographic projection of the second active portion 812 on the base substrate. A partial structure of the first gate line 3G1 may be used to form a top gate of the second transistor T2. At the same time, the first gate line 3G1 may be connected to the third gate line 2G1 through a via hole located in an edge wiring region of the display panel. As shown in FIG. 7 and FIG. 20, in a same pixel driving circuit, the orthographic projection of the second conductive portion 12 on the base substrate may be located between the orthographic projection of the first gate line 3G1 on the base substrate and the orthographic projection of the enable signal line EM on the base substrate; the orthographic projection of the first reset signal line 3Re1 on the base substrate may be located on a side of the orthographic projection of the first gate line 3G1 on the base substrate away from the orthographic projection of the second conductive portion 12 on the base substrate. The orthographic projection of the second gate line G2 on the base substrate may be located between the orthographic projection of the first gate line 3G1 on the base substrate and the orthographic projection of the first reset signal line 3Re1 on the base substrate. The orthographic projection of the second reset signal line Re2 on the base substrate may be located on a side of the orthographic projection of the enable signal line EM on the base substrate away from the orthographic projection of the second conductive portion 12 on the base substrate. In addition, the display panel can use the third conductive layer as a mask to perform conductorization processing on the second active layer, that is, a region of the second active layer covered by the third conductive layer can form a channel region of a transistor, and a region of the second active layer not covered by the third conductive layer forms a conductor structure.

As shown in FIGS. 7, 14, and 21, the fourth conductive layer may include a first bridge portion 41, a second bridge portion 42, a third bridge portion 43, a fourth bridge portion 44, a fifth bridge portion 45, a sixth bridge portion 46, and the second initialization signal line Vinit2. The first bridge portion 41 may be connected to the first connection portion 22 through two via holes H, and connected to the ninth active portion 79 through a via hole to connect the first electrode of the fifth transistor and the second electrode of the capacitor C. It should be noted that in this example embodiment, the black squares represent the positions of via holes, and this example embodiment only labels some of the via holes. The first bridge portion 41 may be mirror symmetrical with respect to a mirror symmetry plane of the first pixel driving circuit P1 and the second pixel driving circuit P2. The second bridge portion 42 may be connected to the tenth active portion 7 10 through a via hole to connect the second electrode of the sixth transistor T6 and the first electrode of the seventh transistor T7. The third bridge portion 43 may be connected to the eleventh active portion 711 and the twelfth active portion 813 through via holes respectively to connect the second electrode of the second transistor T2, the first electrode of the sixth transistor T6, and the second electrode of the driving transistor T3. The fourth bridge portion 44 may be connected to the second conductive portion 12 and the second active layer and between the first active portion 811 and the second active portion 812 respectively through via holes to connect the first electrode of the second transistor T2 and the gate of the driving transistor. As shown in FIG. 11, an opening 211 is formed in the first conductive portion 21. An orthographic projection of a via hole connected between a second conductive portion 12 and the fourth bridge portion 44 on the base substrate is located within the orthographic projection of the opening 211 on the base substrate, so that the conductive structure in the via hole and the first conductive portion 21 are insulated from each other. The fifth bridge portion 45 may be connected to first initialization signal line Vinit1 and the second active layer on a side of the first active portion 811 away from the second active portion 812 through via holes respectively to connect the second electrode of the first transistor and the first initialization signal terminal. In two repetition units which are adjacent in the row direction, two adjacent pixel driving circuits may share the same fifth bridge portion 45. The sixth bridge portion 46 may be connected to the first active layer on a side of the fourth active portion 74 away from the third active portion 73 through a via hole to connect the first electrode of the fourth transistor. The second initialization signal line Vinit2 may be used to provide the second initialization signal terminal in FIG. 1, and the second initialization signal line Vinit2 may be connected to the first active layer on a side of the seventh active portion 77 away from the sixth active portion 76 through a via hole, to connect the second electrode of the seventh transistor and the second initialization signal terminal.

As shown in FIGS. 7, 14, and 21, the second bridge portion 42 and the third bridge portion 43 may be arranged oppositely in the column direction Y, that is, a region covered by the orthographic projection of the second bridge portion 42 extending infinitely along the column direction Y intersects with a region covered by the orthographic projection of the third bridge portion 43 on the base substrate extending infinitely along the column direction Y. As shown in FIGS. 7, 14, and 21, the distance between orthographic projections of second bridge portions 42 which are adjacent in the row direction on the base substrate is equal to L5, and the distance between orthographic projections of a second bridge portion 42 and a first bridge portion 41 which are adjacent in the row direction on the base substrate is equal to L6, and L5/L6 is larger than or equal to 0.8 and less than or equal to 1.2. For example, L5/L6 may be equal to 0.8, 0.9, 1, 1.1, or 1.2.

As shown in FIGS. 7, 15, and 22, the fifth conductive layer may include a plurality of power lines VDD, a plurality of data lines Da, and a seventh bridge portion 57. The orthographic projections of the power lines VDD on the base substrate and the orthographic projections of the data lines Da on the base substrate may both extend along the column direction Y. A power line VDD may be used to provide the first power terminal in FIG. 1, and a data line Da may be used to provide the data signal terminal in FIG. 1. As shown in FIG. 7, each column of pixel driving circuits may be provided with a corresponding power line. A power line VDD in the first pixel driving circuit P1 may be connected to the first bridge portion 41 through a via hole, and a power line VDD in the second pixel driving circuit P2 may be connected to the same first bridge 41 through a via hole, thereby connecting the first electrode of the fifth transistor and the first power terminal. A data line Da may be connected to the sixth bridge portion 46 through a via hole to connect the first electrode of the fourth transistor and the data signal terminal. The seventh bridge portion 57 may be connected to the second bridge portion 42 through a via hole to connect the first electrode of the seventh transistor. As shown in FIG. 15, a power line VDD may include a first extension portion VDD1, a second extension portion VDD2, and a third extension portion VDD3. The second extension portion VDD2 is connected between the first extension portion VDD1 and the third extension portion VDD3. The size of an orthographic projection of the second extension portion VDD2 on the base substrate in the row direction X may be larger than the size of an orthographic projection of the first extension portion VDD1 on the base substrate in the row direction X, and the size of the orthographic projection of the second extension portion VDD2 on the base substrate in the row direction X may be larger than the size of an orthographic projection of the third extension portion VDD3 on the base substrate in the row direction X. The orthographic projection of the second extended portion VDD2 on the base substrate may cover the orthographic projection of the first active portion 811 on the base substrate and the orthographic projection of the second active portion 812 on the base substrate. The second extension portion VDD2 can reduce the influence of light on the characteristics of the first transistor T1 and the second transistor T2. In two repetition units which are adjacent in the row direction, second extensions portions VDD2 in two adjacent pixel driving circuits may be connected to each other, so that the power lines VDD and the first conductive portion 21 can form a grid structure, and the power lines of the grid structure can reduce a voltage drop of a power signal on the power lines.

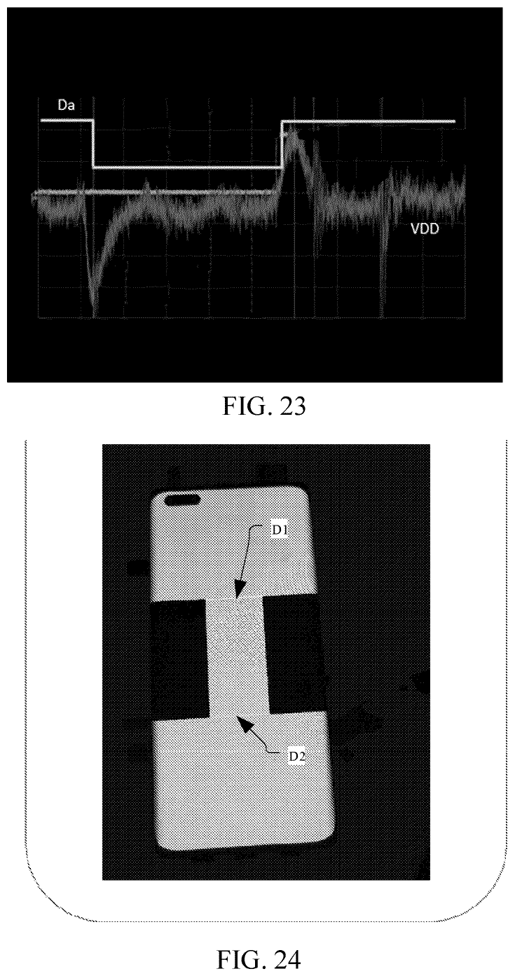

FIG. 23 is an actual measured timing diagram of a data signal terminal and a first power terminal of a pixel driving circuit in related art. In this figure, Da represents the timing of the data signal terminal, and VDD represents the timing of the first power terminal. When a gray level of a sub-pixel unit changes from a high gray level to a low gray level, the signal voltage of the data signal terminal Da becomes high. Due to the parasitic capacitance between the data signal line and the power line, the first power terminal VDD is pulled high. The voltage of the first power terminal VDD pulls the voltage of the node N low during the recovery process, thereby generating a bright line. When the gray level of the sub-pixel unit changes from a low gray level to a high gray level, the signal voltage of the data signal terminal Da becomes low. Due to the parasitic capacitance between the data signal line and the power line, the first power terminal VDD is pulled low. The voltage of the first power terminal VDD pulls the voltage of the node N high during the recovery process, thereby generating a dark line. As shown in FIG. 24, it is a display state diagram of a display panel presenting a specific screen in the related art. This screen will produce abnormal bright line D1 and dark line D2 due to the coupling effect between the above-mentioned data line and power line.

In view of the above, as shown in FIGS. 7, 15, and 22, in an example embodiment, a data line Da may include a straight line extension portion Dal, and an orthographic projection of the straight line extension portion Dal on the base substrate extend straightly along the column direction Y. In a same repetition unit, orthographic projections of two data lines Da on the base substrate are located between orthographic projections of two power lines VDD on the base substrate; the minimum distance in the row direction between the orthographic projection of a straight line extension portion Dal of a data line Da on the base substrate and the orthographic projection of an adjacent power line VDD on the base substrate is L1; the minimum distance in the row direction between orthographic projections of straight line extension portions of two data lines on the base substrate is L2, and L1/L2 may be larger than or equal to 1.4. For example, L1/L2 may be equal to 1.4, 1.5, 2, 3, 4, or 5, etc.

As shown in FIGS. 7, 14 and 21, the first bridge portion 41 may include a first via connection portion 411 for connecting the ninth active portion 79 and two second via connection portions 411 for connecting a power line VDD. The two second via hole connection portions 412 are connected to both sides of the first via hole connection portion 411, and the first bridge portion 41 is provided with a notch 413 between the first via hole connection portion 411 and the second via hole connection portions 412. The size of an orthographic projection of the notch on the base substrate in the row direction is L4, and L1/L4 is larger than or equal to 0.9 and less than or equal to 1.1. For example, L1/L4 may be equal to 0.9, 1, or 1.1 etc. The setting of the size of the notch 413 in the first bridge portion 41 can enable the first bridge portion 41 to serve as a positioning structure during the patterning process for the fifth conductive layer.

This example embodiment can reduce the coupling effect between a data line and a power line by increasing the distance between the data line Da and the power line VDD, thereby improving the above technical problem of crosstalk between the data line and the power line.

As shown in FIGS. 7, 15, and 22, in an example embodiment, the minimum distance in the row direction between the orthographic projection of a straight line extension portion Dal of a data line Da on the base substrate and the orthographic projection of a power line VDD on the base substrate is L1, the size of the orthographic projection of the straight line extension portion Dal of the data line on the base substrate in the row direction is L3, and L1/L 3 is larger than or equal to 1.4 and less than or equal to 3. For example, L1/L3 may be equal to 1.4, 1.5, 1.8, 2, 2.5, or 3, etc. This setting also reduces the coupling effect between the data line Da and the power line VDD by increasing the distance between the data line Da and the power line VDD, thereby improving the display effect.

As shown in FIG. 7, the electrode layer may have an R electrode portion R, a G electrode portion G, and a B electrode portion B. The electrode portions may be connected to the seventh bridge portion 57 through via holes to connect the first electrode of the seventh transistor. As shown in FIG. 7, the R electrode portion is connected to the seventh bridge portion through a first via hole H1, and the R electrode portion R includes a first side R21 and a second side R22 arranged oppositely. The orthographic projections of the first side R21 and the second side R22 of the R electrode portion on the base substrate extend along the column direction Y. In an R electrode portion and a G electrode portion located in a same row and adjacent columns, the orthographic projection of the first side R21 of the R electrode portion on the base substrate is located between the orthographic projection of the second side R22 of the R electrode portion on the base substrate and the orthographic projection of the G electrode portion G on the base substrate. An extension line of the orthographic projection of the first side R21 of the R electrode portion on the base substrate passes through the orthographic projection of the first via hole H1 on the base substrate. The B electrode portion is connected to the seventh bridge portion 57 through a second via hole H2. The B electrode portion includes a third side B23 and a fourth side B24 arranged oppositely. The orthographic projections of the third side B23 and the fourth side B24 of the B electrode portion on the base substrate both extend along the column direction Y. Extension lines of the orthographic projections of the third side B23 and the fourth side B24 of the B electrode portion on the base substrate are located on both sides of the orthographic projection of the second via hole H2 on the base substrate.

It should be noted that, as shown in FIGS. 7, 21, and 22, black squares drawn on a side of the fourth conductive layer away from the base substrate represent via holes of the fourth conductive layer connecting to other layers facing a side of the base substrate; black squares drawn on a side of the fifth conductive layer away from the base substrate represent via holes of the fifth conductive layer connecting to other layers facing a side of the base substrate; black squares drawn on a side of the electrode layer away from the base substrate represent via holes of the electrode layer connecting to other layers facing a side of the base substrate. The black squares only represent the locations of the via holes. Different via holes represented by black squares at different positions can penetrate different insulating layers.

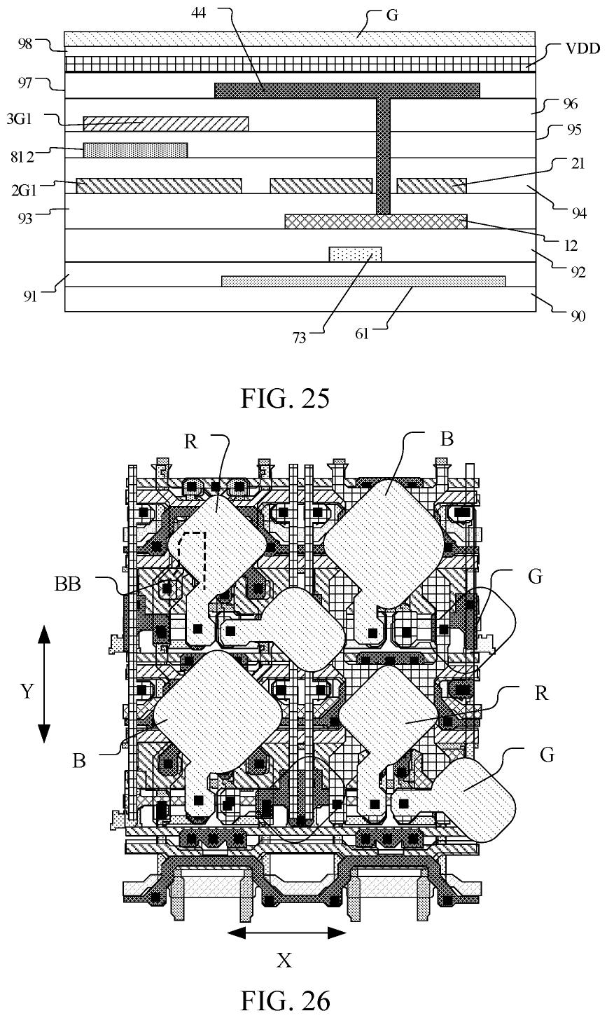

FIG. 25 is a partial cross-sectional view of the display panel taken along a dotted line AA in FIG. 7. As shown in FIG. 25, the display panel may further include a first insulating layer 91, a second insulating layer 92, a third insulating layer 93, a fourth insulating layer 94, a fifth insulating layer 95, a first dielectric layer 96, a first planarization layer 97, and a second planarization layer 98. The base substrate 90, the light-shielding layer, the first insulating layer 91, the first active layer, the second insulating layer 92, the first conductive layer, the third insulating layer 93, second conductive layer, the fourth insulating layer 94, the second active layer, the fifth insulating layer 95, the third conductive layer, the first dielectric layer 96, the fourth conductive layer, the first planarization layer 97, the fifth conductive layer, the second planarization layer 98 and the electrode layer are stacked in sequence. The first insulating layer 91, the second insulating layer 92, the third insulating layer 93, the fourth insulating layer 94 and the fifth insulating layer 95 may have a single-layer structure or a multi-layer structure, and the material of the first insulating layer 91, the second insulating layer 92, the third insulating layer 93, the fourth insulating layer 94 and the fifth insulating layer 95 may be at least one of: silicon nitride, silicon oxide, and silicon oxynitride. The first dielectric layer 96 may be a silicon nitride layer. The materials of the first planarization layer 97 and the second planarization layer 98 may be organic materials, such as polyimide (PI), polyethylene glycol terephthalate (PET), polyethylene naphthalate two formic acid glycol ester (PEN), silicon on glass (SOG) or other materials. The base substrate 90 may include a glass substrate, a blocking layer, and a polyimide layer that are stacked in sequence. The blocking layer may be an inorganic material. The material of the first conductive layer, the second conductive layer, and the third conductive layer may be one of molybdenum, aluminum, copper, titanium, niobium or an alloy, or a molybdenum/titanium alloy or a laminated structure of molybdenum/titanium. The material of the fourth conductive layer and the fifth conductive layer may include a metal material, for example, it may be one of molybdenum, aluminum, copper, titanium, niobium or an alloy, or a molybdenum/titanium alloy or a laminated structure of molybdenum/titanium, or it may be a laminated structure of titanium/aluminum/titanium. The electrode layer may include an indium tin oxide layer.

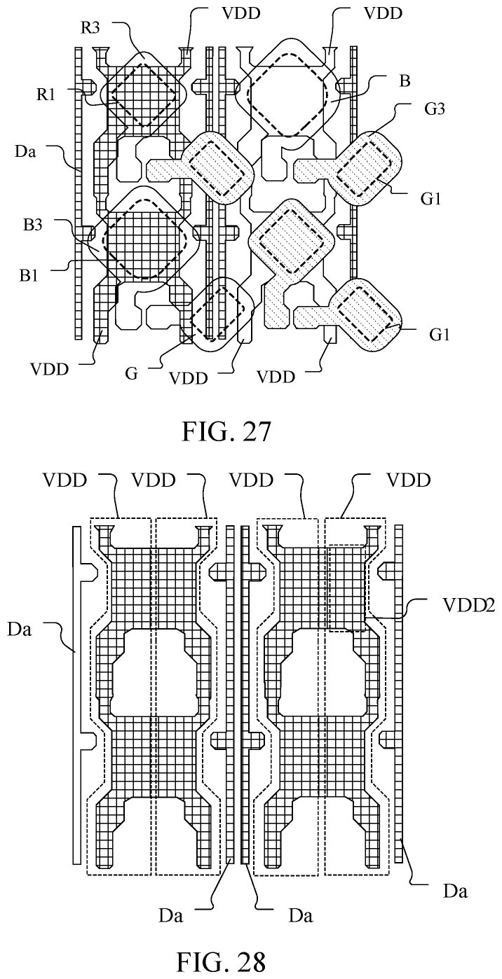

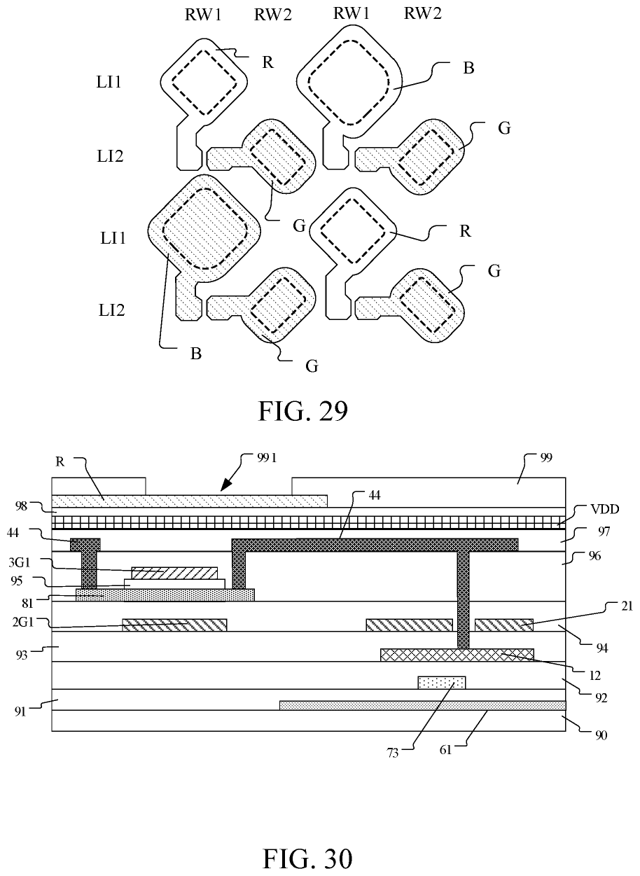

As shown in FIGS. 26 to 29, FIG. 26 is a structural layout of a display panel according to another example embodiment of the present disclosure. FIG. 27 is a structural layout of a fifth conductive layer and an electrode layer in FIG. 26. FIG. 28 is a structural layout of the fifth conductive layer in FIG. 26. FIG. 29 is a structural layout of the electrode layer in FIG. 26. The display panel may be different from the display panel shown in FIG. 7 only in the structural layout of the electrode layer. The plurality of electrode portions include a plurality of R electrode portions R, a plurality of G electrode portions G, and a plurality of B electrode portions B. A plurality of the electrode portions are distributed in an array along row and column directions. The plurality of electrode portions include a first electrode column RW1 and a second electrode column RW2 that are alternately distributed in the row direction. The first electrode column RW1 includes an R electrode portion and a B electrode portion that are distributed sequentially and alternately in the column direction. The second electrode column RW2 includes a plurality of G electrode portions spaced apart in the column direction. The plurality of electrode portions include a first electrode row LI1 and a second electrode row LI2 that are distributed sequentially and alternately in the column direction. The first electrode row L1 includes an R electrode portion and a B electrode portion that are distributed sequentially and alternately along the row direction. The second electrode row L2 includes a plurality of G electrode portions spaced apart along the row direction. Regions covered by orthographic projections of two electrode portions in adjacent electrode columns on the base substrate extending in the column direction may overlap, and regions covered by orthographic projections of two electrode portions in adjacent electrode rows on the base substrate extending in the row direction may overlap.

In an example embodiment, as shown in FIGS. 26 to 29, an overlapping area between an orthographic projection of an R electrode portion R on the base substrate and an orthographic projection of a power line VDD on the base substrate is S10, the area of an orthographic projection of a body portion R1 of the R electrode portion on the base substrate is S11, and S10/S11 is larger than or equal to 1.1 and less than or equal to 2. For example, S10/S11 may be 1.1, 1.2, 1.3, 1.4, 1.5, 1.6, 1.7, 1.8, 19, or 2, etc. An overlapping area between an orthographic projection of a G electrode portion on the base substrate and an orthographic projection of a power line VDD on the base substrate is S12, the area of an orthographic projection of a body portion G1 of the G electrode portion on the base substrate is S13, and S12/S13 is larger than or equal to 0.2 and less than or equal to 1. For example, S12/S13 may be equal to 0.2, 0.3, 0.4, 0.5, 0.6, 0.7, 0.8, 0.9, or 1, etc. An overlapping area between an orthographic projection of a B electrode portion on the base substrate and an orthographic projection of a power line VDD on the base substrate is S14, the area of an orthographic projection of a body portion B1 of the B electrode portion on the base substrate is S15, and S14/S15 is larger than or equal to 0.8 and less than or equal to 1.5. For example, S14/S15 may be equal to 0.8, 0.9, 1, 1.1, 1.2, 1.3, 1.4, or 1.5.

In an example embodiment, as shown in FIGS. 26 to 29, the area of the orthographic projection of the body portion R1 of the R electrode portion on the base substrate is S11, an overlapping area between an orthographic projection of a supplemental portion R3 of the R electrode portion on the base substrate and the orthographic projection of a power line VDD on the base substrate is S16, and S16/S11 is larger than or equal to 0.2 and less than or equal to 1.1. For example, S16/S11 may be equal to 0.2, 0.3, 0.4, 0.5, 0.6, 0.7, 0.8, 0.9, 1, or 1.1, etc. The area of the orthographic projection of the body portion G1 of the G electrode portion on the base substrate is S13, an overlapping area between an orthographic projection of a supplemental portion G3 of the G electrode portion on the base substrate and an orthographic projection of a power line VDD on the base substrate is S17, and S17/S13 is larger than or equal to 0.15 and less than or equal to 0.95. For example, S17/S13 may be equal to 0.15, 0.2, 0.3, 0.4, 0.5, 0.6, 0.7, 0.8, or 0.95, etc. The area of the orthographic projection of the body portion B1 of the B electrode portion on the base substrate is S15, and overlapping area between an orthographic projection of a supplemental portion B3 of the B electrode portion on the base substrate and an orthographic projection of a power line VDD on the base substrate is S18, and S18/S15 is larger than or equal to 0.05 and less than or equal to 0.4. For example, S18/S15 may be equal to 0.05, 0.1, 0.2, 0.3, or 0.4, etc.

In an example embodiment, as shown in FIGS. 26 to 29, the orthographic projection of the R electrode portion on the base substrate overlaps with orthographic projections of two connected second extension portions VDD2 on the base substrate, and the orthographic projection of the B electrode portion on the base substrate overlaps with orthographic projections of two connected second extension portions VDD2 on the base substrate, and the orthographic projection of the G electrode portion on the base substrate overlaps with orthographic projections of two data lines Da in the same repetition unit on the base substrate.

FIG. 30 is a partial cross-sectional view along a dotted line BB in FIG. 26. The display panel may include a first insulating layer 91, a second insulating layer 92, a third insulating layer 93, a fourth insulating layer 94, a fifth insulating layer 95, a first dielectric layer 96, a first planarization layer 97, a second planarization layer 98, and a pixel defining layer 99. The base substrate 90, the light-shielding layer, the first insulating layer 91, the first active layer, the second insulating layer 92, the conductive layer, the third insulating layer 93, the second conductive layer, the fourth insulating layer 94, the second active layer, the fifth insulating layer 95, the third conductive layer, the first dielectric layer 96, the four conductive layer, the first planarization layer 97, the fifth conductive layer, the second planarization layer 98, the electrode layer, and the pixel defining layer 99 are stacked in sequence. Pixel openings 991 are provided in the pixel definition layer 99. As shown in FIG. 30, the fifth insulating layer 95 may be a patterned structure for isolating the third conductive layer and the second active layer. It should be understood that in other example embodiments, the fifth insulating layer 95 may also have a whole-layer structure. In addition, the second insulating layer 92 located between the first active layer and the first conductive layer may also have a patterned structure.

It should be noted that the scale of the drawings in the present disclosure may be used as a reference in actual processes, but is not limited thereto. For example: the width-to-length ratios of channels, the thickness and spacing of film layers, the width and spacing of signal lines can be adjusted according to actual needs. The number of pixels in the display substrate and the number of sub-pixels in each pixel are not limited to the numbers shown in the drawings. The drawings described in the present disclosure are only structural schematic diagrams. In addition, first, second or other qualifiers are only used to define different structure names and are not intended to indicate any specific order.

An example embodiment further provides a display apparatus, which includes the display panel described in the above embodiments. The display apparatus may be a display apparatus such as a mobile phone, a tablet computer, or a television.

Other embodiments of the disclosure will be readily apparent to those skilled in the art from consideration of the specification and practice of the disclosure herein. The present disclosure is intended to cover any variations, uses, or adaptations of the present disclosure that follow the general principles of the present disclosure and include common knowledge or customary technical means in the this art that are not disclosed herein. It is intended that the specification and examples should be considered as exemplary only, with a true scope and spirit of the present disclosure being indicated by the appended claims.

It is to be understood that the present disclosure is not limited to the precise structures described above and illustrated in the accompanying drawings, and various modifications and changes may be made without departing from the scope of the present disclosure. The scope of the present disclosure is limited only by the appended claims.

What is claimed is:

1. A display panel, comprising:
a base substrate;
a fifth conductive layer located on a side of the base substrate, wherein the fifth conductive layer comprises at least one power line;
an electrode layer located on a side of the fifth conductive layer away from the base substrate, wherein the electrode layer comprises a plurality of electrode portions, at least one of the electrode portions comprises a body portion and a supplemental portion which are connected with each other, and an orthographic projection of the supplemental portion on the base substrate at least partially overlaps with an orthographic projection of a corresponding power line on the base substrate; and
a pixel defining layer located on a side of the electrode layer away from the base substrate and comprising a plurality of pixel openings, wherein the plurality of pixel openings are arranged in one-to-one correspondence with the plurality of electrode portions, and an orthographic projections of one of the pixel openings on the base substrate overlaps with an orthographic projections of a body portions of a corresponding electrode portions on the base substrate.

2. The display panel according to claim 1, wherein:
the plurality of electrode portions comprise a first electrode portion, a second electrode portion and a third electrode portion of three different colors;
an overlapping area between an orthographic projection of the first electrode portion on the base substrate and an orthographic projection of a power line corresponding to the first electrode portion on the base substrate is larger than an overlapping area between an orthographic projection of the second electrode portion on the base substrate and an orthographic projection of a power line corresponding to the second electrode portion on the base substrate; and
the overlapping area between the orthographic projection of the first electrode portion on the base substrate and the orthographic projection of the power line corresponding to the first electrode portion on the base substrate is larger than an overlapping area between an orthographic projection of the third electrode portion on the base substrate and an orthographic projection of a power line corresponding to the third electrode portion on the base substrate.

3. The display panel according to claim 2, wherein:
the first electrode portion is a B electrode portion corresponding to a blue sub-pixel unit, the second electrode portion is an R electrode portion corresponding to a red sub-pixel unit, and the third electrode portion is a G electrode portion corresponding to a green sub-pixel unit;
the overlapping area between the orthographic projection of the first electrode portion on the base substrate and the orthographic projection of the power line corresponding to the first electrode portion on the base substrate is larger than the overlapping area between the orthographic projection of the second electrode portion on the base substrate and the orthographic projection of the power line corresponding to the second electrode portion on the base substrate; and
the overlapping area between the orthographic projection of the second electrode portion on the base substrate and the orthographic projection of the power line corresponding to the second electrode portion on the base substrate is larger than the overlapping area between the orthographic projection of the third electrode portion on the base substrate and the orthographic projection of the power line corresponding to the third electrode portion on the base substrate.

4. The display panel according to claim 2, wherein:
the display panel further comprises a plurality of pixel driving circuits distributed in rows and columns, at least one of the pixel driving circuits comprises a driving transistor and a fourth transistor, and a first electrode of the fourth transistor is connected to a data line, and a second electrode of the fourth transistor is connected to a first electrode of the driving transistor; and
an overlapping area between the orthographic projection of the second electrode portion on the base substrate and an orthographic projection of a data line on the base substrate is larger than an overlapping area between the orthographic projection of the third electrode portion on the base substrate and the orthographic projection of a data line on the base substrate, and the overlapping area between the orthographic projection of the third electrode portion on the base substrate and the orthographic projection of a data line on the base substrate is larger than an overlapping area between the orthographic projection of the first electrode portion on the base substrate and the orthographic projection of a data line on the base substrate.

5. The display panel according to claim 1, wherein the plurality of electrode portions comprise: a plurality of R electrode portions, a plurality of G electrode portions and a plurality of B electrode portions;
wherein two G electrode portions distributed along a column direction are provided between an R electrode portion and a B electrode portion which are adjacent in a row direction.

6. The display panel according to claim 5, wherein an overlapping area between an orthographic projection of the R electrode portion on the base substrate and an orthographic projection of a power line corresponding to the R electrode portion on the base substrate is S1, an area of an orthographic projection of a body portion of the R electrode portion on the base substrate is S2, and S1/S2 is larger than or equal to 0.8 and less than or equal to 1.9.

7. The display panel according to claim 5, wherein an overlapping area between an orthographic projection of the G electrode portion on the base substrate and an orthographic projection of a power line corresponding to the G electrode portion on the base substrate is S3, an area of an orthographic projection of a body portion of the G electrode portion on the base substrate is S4, and S3/S4 is larger than or equal to 1 and less than or equal to 1.7.

8. The display panel according to claim 5, wherein an overlapping area between an orthographic projection of the B electrode portion on the base substrate and an orthographic projection of a power line corresponding to the B electrode portion on the base substrate is S5, an area of an orthographic projection of a body portion of the B electrode portion on the base substrate is S6, and S5/S6 is larger than or equal to 1.6 and less than or equal to 2.

9. The display panel according to claim 5, wherein:
an area of an orthographic projection of a body portion of the R electrode portion on the base substrate is S2, an overlapping area between an orthographic projection of a supplemental portion of the R electrode portion on the base substrate and the orthographic projection of the power line corresponding to the R electrode portion on the base substrate is S7, and S7/S2 is larger than or equal to 0.04 and less than or equal to 1.14.

10. The display panel according to claim 5, wherein:
a supplemental portion of a G electrode portion comprises a first supplemental portion and a second supplemental portion;
in an R electrode portion and the G electrode portion located in a same row and adjacent columns:
an orthographic projection of the first supplemental portion of the G electrode portion on the base substrate is located on a side of an orthographic projection of a body portion of the G electrode portion on the base substrate facing an orthographic projection of the R electrode portion on the base substrate;
an orthographic projection of the second supplemental portion of the G electrode portion on the base substrate is located on a side of the orthographic projection of the body portion of the G electrode portion on the base substrate facing an orthographic projection of another G electrode portion on the base substrate; and
an area of the orthographic projection of the body portion of the G electrode portion on the base substrate is S4, an overlapping area between an orthographic projection of the supplemental portion of the G electrode portion on the base substrate and the orthographic projection of the power line corresponding to the G electrode portion on the base substrate is S8, and S8/S4 is larger than or equal to 0.1 and less than or equal to 0.8.

11. The display panel according to claim 5, wherein:
a supplemental portion of the B electrode portion comprises a third supplemental portion and a fourth supplemental portion;
in the B electrode portion and a G electrode portion located in a same row and adjacent columns:
an orthographic projection of the third supplemental portion of the B electrode portion on the base substrate is located on a side of an orthographic projection of a body portion of the B electrode portion on the base substrate facing an orthographic projection of the G electrode portion on the base substrate; and
an orthographic projection of the fourth supplemental portion of the B electrode portion on the base substrate is located on a side the orthographic projection of the body portion of the B electrode portion on the base substrate away from the orthographic projection of the third supplemental portion of the B electrode portion on the base substrate;
an area of the orthographic projection of the body portion of the B electrode portion on the base substrate is S6, an overlapping area between an orthographic projection of the supplemental portion of the B electrode portion on the base substrate and the orthographic projection of the power line corresponding to the B electrode portion on the base substrate is S9, and S9/S6 is larger than or equal to 0.1 and less than or equal to 0.5.

12. The display panel according to claim 5, wherein:
the fifth conductive layer further comprises a plurality of seventh bridge portions, and the plurality of seventh bridge portions are arranged in one-to-one correspondence with the plurality of electrode portions, and electrode portions are connected to corresponding seventh bridge portions through via holes;
an R electrode portion is connected to a seventh bridge portion through a first via hole, the R electrode portion comprises a first side and a second side arranged oppositely, and orthographic projections of the first side and the second side of the R electrode portion on the base substrate extend along the column direction,
in the R electrode portion and a G electrode portion located in a same row and adjacent columns:
the orthographic projection of the first side of the R electrode portion on the base substrate is located between the orthographic projection of the second side of the R electrode portion on the base substrate and an orthographic projection of the G electrode portion on the base substrate; and
an extension line of the orthographic projection of the first side on the base substrate passes through an orthographic projection of the first via hole on the base substrate;
a B electrode portion is connected to a seventh bridge portion through a second via hole, the B electrode portion comprises a third side and a fourth side arranged oppositely, orthographic projections of the third side and the fourth side of the B electrode portion on the base substrate extend along the column direction, and extension lines of the orthographic projections of the third side and the fourth side of the B electrode portion on the base substrate are located on both sides of an orthographic projection of the second via hole on the base substrate.

13. The display panel according to claim 2, wherein:
the display panel further comprises a pixel driving circuit, and the pixel driving circuit comprises a driving transistor, a first transistor, a second transistor, a sixth transistor and a seventh transistor;
a first electrode of the first transistor is connected to a gate of the driving transistor, and a second electrode of the first transistor is connected to a first initialization signal line;
a first electrode of the second transistor is connected to the gate of the driving transistor, and a second electrode of the second transistor is connected to a second electrode of the driving transistor;
a first electrode of the sixth transistor is connected to the second electrode of the driving transistor;
a first electrode of the seventh transistor is connected to a second electrode of the sixth transistor, and a second electrode of the seventh transistor are connected to a second initialization signal line;
wherein the display panel further comprises:
a first active layer located between the base substrate and the fifth conductive layer, wherein the first active layer comprises a third active portion, a sixth active portion, a seventh active portion, a tenth active portion and an eleventh active portion; wherein:
the third active portion is used to form a channel region of the driving transistor;
the sixth active portion is used to form a channel region of the sixth transistor;
the seventh active portion is used to form a channel region of the seventh transistor;
the tenth active portion is connected between the seventh active portion and the sixth active portion; and
the eleventh active portion is connected between the sixth active portion and the third active portion;
a second active layer located between the first active layer and the fifth conductive layer, wherein the second active layer comprises a first active portion and a second active portion and a twelfth active portion; wherein:
the first active portion is used to form a channel region of the first transistor;
the second active portion is connected to the first active portion and is used to form a channel region of the second transistor, and
the twelfth active portion is connected to an end of the second active portion away from the first active portion; and
a fourth conductive layer located between the second active layer and the fifth conductive layer, wherein the fourth conductive layer comprises a second bridge portion and a third bridge portion, the second bridge portion is connected to the tenth active portion through a via hole, and the third bridge portion is connected to the eleventh active portion and the twelfth active portion through via holes, respectively; and
wherein the second bridge portion and the third bridge portion are arranged oppositely in a column direction.

14. The display panel according to claim 2, wherein the display panel comprises a plurality of repetition units distributed along a row direction and a column direction, each of the repetition units comprises two pixel driving circuits, the two pixel driving circuits comprises a first pixel driving circuit and a second pixel driving circuit distributed along the row direction, and the first pixel driving circuit and the second pixel driving circuit are arranged in mirror symmetry;
wherein at least one of the pixel driving circuits comprises a driving transistor, a sixth transistor and a seventh transistor, a first electrode of the sixth transistor is connected to a second electrode of the driving transistor, a first electrode of the seventh transistor is connected to a second electrode of the sixth transistor, and a second electrode of the seventh transistor is connected to a second initialization signal line;
wherein the display panel further comprises:
a first active layer located between the base substrate and the fifth conductive layer, wherein the first active layer comprises a third active portion, a sixth active portion, a seventh active portion and a tenth active portion; wherein:
the third active portion is used to form a channel region of the driving transistor;
the sixth active portion is used to form a channel region of the sixth transistor;
the seventh active portion is used to form a channel region of the seventh transistor; and
the tenth active portion is connected between the seventh active portion and the sixth active portion; and
a fourth conductive layer located between the first active layer and the fifth conductive layer, wherein the fourth conductive layer comprises a first bridge portion and a second bridge portion, the second bridge portion is connected to the tenth active portion through a via hole, the first bridge portion and the repetition units are arranged in one-to-one correspondence, and the first bridge portion is connected to the power line through a via hole;
wherein a distance between orthographic projections of second bridge portions adjacent in the row direction on the base substrate is equal to L5, a distance between orthographic projections of a second bridge portion and a first bridge portion adjacent in the row direction on the base substrate is equal to L6, and L5/L6 is larger than or equal to 0.8 and less than or equal to 1.2.

15. The display panel according to claim 2, wherein the display panel comprises a plurality of repetition units distributed along a row direction and a column direction, each of the repetition units comprises two pixel driving circuits, the two pixel driving circuits comprise a first pixel driving circuit and a second pixel driving circuit distributed along the row direction, and the first pixel driving circuit and the second pixel driving circuit are arranged in mirror symmetry;
wherein at least one of the pixel driving circuits comprises a driving transistor, a fourth transistor and a fifth transistor, a first electrode of the fourth transistor is connected to a data line, a second electrode of the fourth transistor is connected to a first electrode of the driving transistor, a first electrode of the fifth transistor is connected to the power line, and a second electrode of the fifth transistor is connected to the first electrode of the driving transistor;
wherein the display panel further comprises:
a first active layer located between the base substrate and the fifth conductive layer, and the first active layer further comprises:
a third active portion used to form a channel region of the driving transistor;
a fifth active portion used to form a channel region of the fifth transistor;
an eighth active portion connected to a side of the fifth active portion away from the third active portion; and
a ninth active portion connected between two eighth active portions in a same repetition unit; and
a fourth conductive layer located between the first active layer and the fifth conductive layer, wherein the fourth conductive layer comprises a plurality of first bridge portions, the plurality of first bridge portions and the plurality of repetition units are arranged in one-to-one correspondence, at least one of the first bridge portions is connected to the ninth active portion through a via hole, and the at least one of the first bridge portions is connected to the power line through a via hole;
wherein at least one of the first bridge portions comprises a first via hole connection portion used for connecting to the ninth active portion and two second via hole connection portions used for connecting to the power line, the two second via hole connections are connected at both sides of the first via hole connection portion, and the first bridge portion is provided with a notch between the first via hole connection portion and the second via hole connection portions;
wherein the orthographic projection of the power line on the base substrate and an orthographic projection of the data line on the base substrate both extend along the column direction, and pixel driving circuits of each column are provided with one corresponding power line and one corresponding data line;
wherein the data line comprises a straight line extension portion, and an orthographic projection of the straight line extension portion on the base substrate extends in a straight line along the column direction;
wherein in a same repetition unit:
orthographic projections of two data lines on the base substrate are located between orthographic projections of two power lines on the base substrate, a minimum distance in the row direction between an orthographic projection of the straight line extension portion of a data line on the base substrate and an orthographic projection of a power line adjacent to the data line on the base station is L1, a size of an orthographic projection of the notch on the base substrate in the row direction is L4, and L1/L4 is larger than or equal to 0.9 and less than or equal to 1.1.

16. The display panel according to claim 1, wherein the display panel comprises a plurality of repetition units distributed along a row direction and a column direction, each of the repetition units comprises two pixel driving circuits, the two pixel driving circuits comprises a first pixel driving circuit and a second pixel driving circuit distributed along the row direction, and the first pixel driving circuit and the second pixel driving circuit are arranged in mirror symmetry;
wherein at least one of the pixel driving circuits comprises a driving transistor, a fourth transistor and a fifth transistor, wherein a first electrode of the fourth transistor is connected to a data line, a second electrode of the fourth transistor is connected to a first electrode of the driving transistor, a first electrode of the fifth transistor is connected to the power line, and a second electrode of the fifth transistor is connected to the first electrode of the driving transistor;
wherein the orthographic projection of the power line on the base substrate and an orthographic projection of the data line on the base substrate both extend along the column direction, and pixel driving circuits of each column are provided with one corresponding power line and one corresponding data line;
wherein the data line comprises a straight line extension portion, and an orthographic projection of the straight line extension portion on the base substrate extends in a straight line along the column direction;
wherein in a same repetition unit:
orthographic projections of two data lines on the base substrate are located between orthographic projections of two power lines on the base substrate, a minimum distance in the row direction between an orthographic projection of the straight line extension portion on the base substrate and an orthographic projection of a power line adjacent to the data line on the base substrate is L1, and a minimum distance in the row direction between orthographic projections of straight line extension portions of two data lines on the base substrate is L2, and L1/L2 is larger than or equal to 1.4.

17. The display panel according to claim 1, wherein:
the display panel comprises a pixel driving circuit, and the pixel driving circuit comprises a driving transistor, a fourth transistor and a fifth transistor;
a first electrode of the fourth transistor is connected to a data line, and a second electrode of the fourth transistor is connected to a first electrode of the driving transistor;
a first electrode of the fifth transistor is connected to the power line, and a second electrode of the fifth transistor is connected to the first electrode of the driving transistor;
the orthographic projection of the power line on the base substrate and an orthographic projection of the data line on the base substrate both extend along a column direction, and pixel driving circuits of each column are provided with one corresponding power line and one corresponding data line;
the data line comprises a straight line extension portion, and an orthographic projection of the straight line extension portion on the base substrate extends in a straight line along the column direction;
a minimum distance in a row direction between an orthographic projection of the straight line extension portion of the data line on the base substrate and the orthographic projection of the power line on the base substrate is L1, and a size of an orthographic projection of the straight line extension portion of the data line on the base substrate in the row direction is L3, and L1/L3 is larger than or equal to 1.4 and less than or equal to 3.

18. The display panel according to claim 1, wherein:
the display panel comprises at least one pixel driving circuit, and at least one pixel driving circuit comprises a driving transistor, a first transistor and a second transistor;
a first electrode of the first transistor is connected to a gate of the driving transistor, and a second electrode of the first transistor is connected to a first initialization signal line;
a first electrode of the second transistor is connected to the gate of the driving transistor, and a second electrode of the second transistor is connected to a second electrode of the driving transistor;
the display panel further comprises:
a first active layer located between the base substrate and the fifth conductive layer, wherein the first active layer comprises a third active portion used to form a channel region of the driving transistor; and
a second active layer located between the first active layer and the fifth conductive layer, wherein second active layer comprises a first active portion and a second active portion, the first active layer is used to form a channel region of the first transistor, and the second active portion is connected to the first active portion and is used to form a channel region of the second transistor;
the power line comprises: a first extension portion, a second extension portion and a third extension portion, and the second extension portion is connected between the first extension portion and the third extension portion;
a size of an orthographic projection of the second extension portion on the base substrate in the row direction is larger than a size of an orthographic projection of the first extension portion on the base substrate in the row direction, and the size of the orthographic projection of the second extension portion on the base substrate in the row direction is larger than a size of an orthographic projection of the third extension portion on the base substrate in the row direction; and
the orthographic projection of the second extension portion on the base substrate covers an orthographic projection of the first active portion on the base substrate and an orthographic projection of the second active portion on the base substrate.

19.-26. (canceled)

27. The display panel according to claim 1, wherein the plurality of electrode portions comprise: a plurality of R electrode portions, a plurality of G electrode portions, and a plurality of B electrode portions;
wherein the plurality of electrode portions are distributed in an array along a row direction and a column direction, the plurality of electrode portions comprise a first electrode column and a second electrode column that are distributed sequentially and alternately along the row direction, the first electrode column comprise an R electrode portion and a B electrode portion which are distributed sequentially and alternately along the column direction, and the second electrode column comprises a plurality of G electrode portions spaced apart along the column direction; and
the plurality of electrode portions comprise a first electrode row and a second electrode row which are distributed sequentially and alternately in the column direction, the first electrode row comprises an R electrode portion and a B electrode portion which are distributed sequentially and alternately along the row direction, and the second electrode row comprises a plurality of G electrode portions spaced apart along the row direction;
wherein:
an overlapping area between an orthographic projection of an R electrode portion on the base substrate and an orthographic projection of a power line corresponding to the R electrode portion on the base substrate is S10, an area of an orthographic projection of a body portion of the R electrode portion on the base substrate is S11, and S10/S11 is larger than or equal to 1.1 and less than or equal to 2;
an overlapping area between an orthographic projection of a G electrode portion on the base substrate and an orthographic projection of a power line corresponding to the G electrode portion on the base substrate is S12, an area of an orthographic projection of a body portion of the G electrode portion on the base substrate is S13, and S12/S13 is larger than or equal to 0.2 and less than or equal to 1; and
an overlapping area between an orthographic projection of a B electrode portion on the base substrate and an orthographic projection of a power line corresponding to the B electrode portion on the base substrate is S14, an area of an orthographic projection of a body portion of the B electrode portion on the base substrate is S15, and S14/S15 is larger than or equal to 0.8 and less than or equal to 1.5;
wherein:
an area of an orthographic projection of a body portion of an R electrode portion on the base substrate is S11, an overlapping area between an orthographic projection of a supplemental portion of the R electrode portion on the base substrate and the orthographic projection of the power line corresponding to the R electrode portion on the base substrate is S16, and S16/S11 is larger than or equal to 0.2 and less than or equal to 1.1;
an area of an orthographic projection of a body portion of a G electrode portion on the base substrate is S13, an overlapping area between an orthographic projection of a supplemental portion of the G electrode portion on the base substrate and the orthographic projection of the power line corresponding to the G electrode portion on the base substrate is S17, and S17/S13 is larger than or equal to 0.15 and less than or equal to 0.95; and
an area of an orthographic projection of a body portion of a B electrode portion on the base substrate is S15, an overlapping area between an orthographic projection of a supplemental portion of the B electrode portion on the base substrate and the orthographic projection of the power line corresponding to the B electrode portion on the base substrate is S18, and S18/S15 is larger than or equal to 0.05 and less than or equal to 0.4.

28.-31. (canceled)
